(19) United States
(12) Patent Application Publication
(10) Pub. No.: US 2025/0351386 A1
(43) Pub. Date: Nov. 13, 2025

(54) Semiconductor Device and Method for Forming the Same

(71) Applicant: Taiwan Semiconductor Manufacturing Co., Ltd., Hsinchu (TW)

(72) Inventors: Cheng-Hao Hou, Hsinchu (TW); Shin-Hung Tsai, Hsinchu (TW); Da-Yuan Lee, Jhubei City (TW); Chi On Chui, Hsinchu (TW)

(21) Appl. No.: 19/274,548

(22) Filed: Jul. 19, 2025

Related U.S. Application Data
(63) Continuation of application No. 18/152,489, filed on Jan. 10, 2023.
(60) Provisional application No. 63/368,367, filed on Jul. 14, 2022.
(60) Provisional application No. 63/378,589, filed on Oct. 6, 2022.

(51) Int. Cl. H10D 1/00; H01L 23/522; H10D 1/68

(52) U.S. Cl. CPC H10D 1/043; H01L 23/5226; H10D 1/042; H10D 1/696; H10D 1/716

(57) ABSTRACT

A method includes forming a first capacitor electrode; forming a first oxygen-blocking layer on the first capacitor electrode; forming an capacitor insulator layer on the first oxygen-blocking layer; forming a second oxygen-blocking layer on the capacitor insulator layer; forming a second capacitor electrode on the second oxygen-blocking layer; and forming a first contact plug that is electrically coupled to the first capacitor electrode and a second contact plug that is electrically coupled to the second capacitor electrode.

### PRIORITY CLAIM AND CROSS-REFERENCE

This application is a continuation of U.S. patent application Ser. No. 18/152,489, filed on Jan. 10, 2023, which claims the benefit U.S. Provisional Application No. 63/368,367, filed on Jul. 14, 2022, and claims the benefit of U.S. Provisional Application No. 63/378,589, filed on Oct. 6, 2022 which applications are hereby incorporated herein by reference.

### BACKGROUND

Metal-Insulator-Metal (MIM) capacitors have been widely used in functional circuits such as mixed signal circuits, analog circuits, Radio Frequency (RF) circuits, Dynamic Random-Access Memories (DRAMs), embedded DRAMs, and logic operation circuits. In system-on-chip applications, different capacitors for different functional circuits have to be integrated on a same chip to serve different purposes. For example, in mixed-signal circuits, capacitors are used as decoupling capacitors and high-frequency noise filters. For DRAM and embedded DRAM circuits, capacitors are used for memory storage, while for RF circuits, capacitors are used in oscillators and phase-shift networks for coupling and/or bypassing purposes. For microprocessors, capacitors are used for decoupling.

Decoupling capacitors are used to decouple some parts of electrical networks from others. Noise caused by certain circuit elements is shunted through the decoupling capacitors, hence reducing the effect of the noise-generating circuit elements on adjacent circuits. In addition, Decoupling capacitors are also used in power supplies, so that the power supplies may accommodate the variations in current-draw, and the noise (variation) in power supply voltage can be suppressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of a package component including one or more Metal-Insulator-Metal (MIM) capacitors, in accordance with some embodiments.

FIGS. 2 through 18 illustrate cross-sectional views of intermediate stages in the formation of a capacitor, in accordance with some embodiments.

FIGS. 19 through 25 illustrate cross-sectional views of intermediate stages in the formation of a capacitor, in accordance with some embodiments.

FIG. 26 illustrates a plan view of a device including multiple capacitors, in accordance with some embodiments.

FIGS. 27A and 27B illustrate cross-sectional views of a capacitor including one barrier layer under forward bias and reverse bias, in accordance with some embodiments.

FIGS. 28A and 28B illustrate cross-sectional views of a capacitor including two barrier layers under forward bias and reverse bias, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A capacitor and the method of forming the same are provided. In accordance with some embodiments, the formation of a Metal-Insulator-Metal (MIM) capacitor includes depositing a bottom barrier layer between the insulator layer and the underlying electrode and depositing a top barrier layer between the insulator layer and the overlying electrode. Forming both a top barrier layer and a bottom barrier layer allows the capacitor to have more consistent behavior in forward bias and reverse bias. In particular, the electric field across the insulator layer may be reduced in both forward bias and reverse bias, which can improve the capacitor's reliability and lifetime. Additionally, forming a capacitor having two barrier layers can result in the capacitance in forward bias and the capacitance in reverse bias to be more similar.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

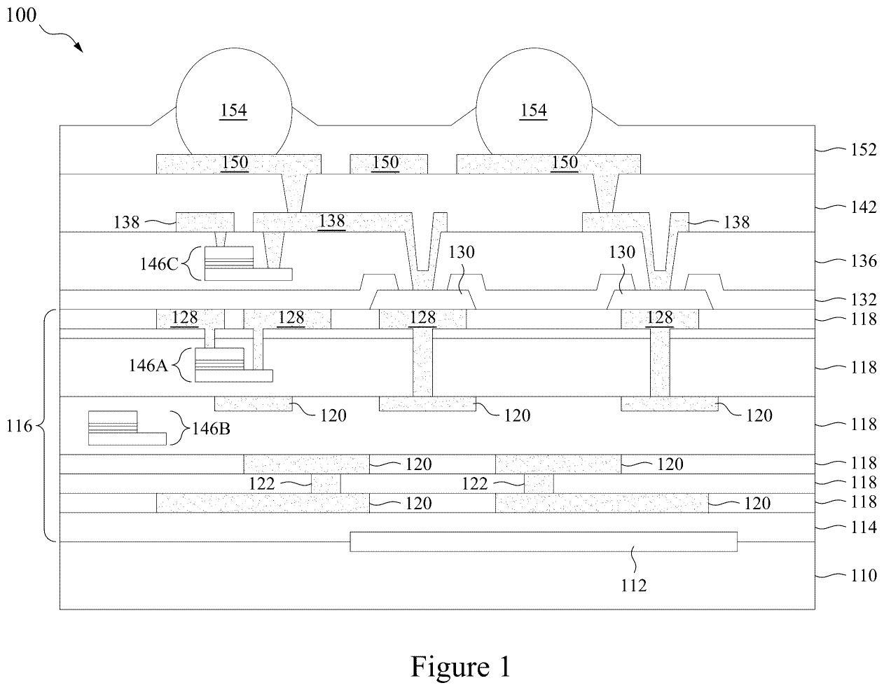

FIG. 1 illustrates a cross-sectional view of a package component 100 including one or more capacitors 146 therein, in accordance with some embodiments. The capacitors 146 may be Metal-Insulator-Metal (MIM) capacitors, in some embodiments. The package component 100 may be, for example, a device wafer, an interposer wafer, a package (e.g., an Integrated Fan-Out (InFO) package or the like), or the like. In the subsequently illustrated embodiments, a device wafer is used as an example structure for the package component 100, but capacitors 146 may be formed in other structures or in other regions of a device wafer, such as in a back-end redistribution structure of a device wafer. Accordingly, one of ordinary skill in the art should appreciate that the formation of the capacitors 146 as described herein is not limited to the examples shown and described in the present disclosure. FIG. 1 shows three example capacitors 146A, 146B, and 146C, and for simplicity “capacitor 146” as used herein may refer to any or all of the capacitors 146A-C or to other capacitors 146 not explicitly shown in FIG. 1.

Referring to FIG. 1, package component 100 includes a substrate 110, in accordance with some embodiments. The substrate 110 may be a semiconductor substrate, such as a bulk semiconductor, a semiconductor-on-insulator (SOI) substrate, or the like, which may be doped (e.g., with a p-type or an n-type dopant) or undoped. The substrate 110 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. The substrate 110 is, in one alternative embodiment, based on an insulating core such as a fiberglass reinforced resin core or organic core. The insulating core may comprise materials such as fiberglass resin, bismaleimide-triazine (BT) resin, printed circuit board (PCB) materials or films, build-up films such as Ajinomoto build-up film (ABF), other laminates, the like, or a combination thereof.

Devices 112 may be formed at or near a surface of the substrate 110, in accordance with some embodiments. The devices 112 may be integrated circuit devices and may include active devices (e.g., transistors, diodes, or the like) and/or passive devices (e.g., capacitors, resistors, or the like). The transistors may be, for example, planar Field-Effect Transistors (FETs), Fin Field-Effect Transistors (FinFETs), Nanostructure Field-Effect Transistors (NSFETs, nanosheet FETs, etc.), or the like.

The package component 100 may further include an Inter-Layer Dielectric (ILD) 114 and an interconnect structure 116 over the substrate 110, in accordance with some embodiments. The ILD 140 may surround and/or cover the devices 112, in some cases. The ILD 140 may include one or more dielectric layers formed of materials such as silicon nitride, silicon oxide, Phospho-Silicate Glass (PSG), Boro-Silicate Glass (BSG), Boron-Doped Phospho-Silicate Glass (BPSG), undoped Silicate Glass (USG), the like, or a combination thereof.

The interconnect structure 116 includes conductive features such as metallization patterns, redistribution layers, or the like formed in one or more dielectric layers 118, in some embodiments. One or more of the dielectric layers 118 may be Inter-Metal Dielectric (IMD) layers, in some cases. The interconnect structure 116 may be electrically connected to the devices 112 to form functional circuits. In some embodiments, the functional circuits formed by the interconnect structure 116 may comprise logic circuits, memory circuits, sense amplifiers, controllers, input/output circuits, image sensor circuits, the like, or a combination thereof.

The dielectric layers 118 may comprise one or more layers of one or more suitable dielectric materials, such as silicon oxide, PSG, BSG, BPSG, USG, a low dielectric constant (low-k) material, fluorosilicate glass (FSG), silicon oxycarbide, carbon-doped oxide (CDO), flowable oxide, a polymer, the like, or a combination thereof. In some cases, the material of one or more dielectric layers 118 may be similar to the material of the ILD 114. The dielectric layers 118 may be deposited using any suitable technique, such as Chemical Vapor Deposition (CVD), Physical Vapor Deposition (PVD), Atomic Layer Deposition (ALD), Plasma-Enhanced ALD (PEALD), Plasma-Enhanced CVD (PECVD), Flowable CVD (FCVD), spin-on, the like, or a combination thereof. Other materials or formation techniques are possible.

The conductive features of the interconnect structure 116 may comprise, for example, conductive lines 120, vias 122, conductive pads 128, or the like. In some embodiments, the conductive pads 128 are formed in a top dielectric layer 118 of the interconnect structure 116. The interconnect structure 116 shown in FIG. 1 is an example, and it should be appreciated that the interconnect structure 116 may include any number of dielectric layers 118 having various conductive features disposed therein. In some embodiments, the interconnect structure 116 may be formed as part of a Back End of Line (BEOL) process or a Middle End of Line (MEOL) process. The conductive features may be formed using a suitable technique such as damascene, dual damascene, or another technique. In some embodiments, the conductive features may comprise a liner (not shown), such as a diffusion barrier layer, an adhesion layer, or the like, and a conductive material. The liner may include titanium, titanium nitride, tantalum, tantalum nitride, the like, or a combination thereof. The conductive material may include copper, a copper alloy, silver, gold, tungsten, cobalt, aluminum, nickel, ruthenium, the like, or a combination thereof. The material(s) of the conductive features may be deposited using a suitable technique such as ALD, CVD, PVD, plating, electro-less plating, the like, or a combination thereof. Other materials or formation techniques are possible.

In some embodiments, metal pads 130 are formed over and electrically coupled to the interconnect structure 116. The metal pads 130 may be electrically coupled to the devices 112 through the conductive pads 128, conductive lines 120, and vias 122 of the interconnect structure 116. The metal pads 130 may be, for example, aluminum pads or aluminum-copper pads, though other materials are possible. In accordance with some embodiments, the metal pads 130 are in physical contact with underlying conductive features of the interconnect structure 116, which may include the topmost conductive features of the interconnect structure 116. For example, as shown in FIG. 1, the metal pads 130 have bottom surfaces that are in physical and electrical contact with top surfaces of conductive pads 128.

As also shown in FIG. 1, a passivation layer 132 may be formed over the interconnect structure 116, in some embodiments. In some embodiments, the passivation layer 132 is formed on conductive pads 128 and on the top dielectric layer 118 of the interconnect structure 116. The passivation layer 132 may comprise one or more layers of dielectric materials such as USG, silicon oxide, silicon nitride, silicon oxynitride, non-porous dielectric materials, low-k dielectric materials, the like, or a combination thereof. Other materials or combinations of materials are possible. The passivation layer 132 may be formed using one or more suitable techniques. The passivation layer 132 is patterned, such that central portions of the metal pads 130 are exposed. In some embodiments, edge portions of the metal pads 130 may remain covered by the passivation layer 132. In some embodiments, some top surfaces of the passivation layer 132 and the metal pads 130 are level.

In some embodiments, a dielectric layer 136 is formed over the metal pads 130 and the passivation layer 132. In some embodiments, the dielectric layer 136 is formed of one or more polymer materials such as polybenzoxazole (PBO), polyimide, benzocyclobutene (BCB), or the like. A polymer material of the dielectric layer 136 may be photosensitive, in some cases. In alternative embodiments, the dielectric layer 136 may be formed of one or more materials such as silicon oxide, silicon nitride, PSG, BSG, BPSG, the like, or a combination thereof. The dielectric layer 136 may be formed, for example, by spin coating, lamination, CVD, or the like. Other materials or techniques are possible.

In some embodiments, a Post-Passivation Interconnect (PPI) 138 may formed over the dielectric layer 136, The PPI 138 may include, for example, line portions over a top surface of the dielectric layer 136 and/or via portions extending into the dielectric layer 136. The PPI 138 may be electrically connected to the metal pads 130, in some embodiments. The PPI 138 may be formed of one or more conductive materials such as copper, a copper alloy, titanium, tungsten, aluminum, or the like. Other materials are possible.

A dielectric layer 142 may be formed over the dielectric layer 136 and the PPI 138, in some embodiments. The dielectric layer 142 may be formed of one or more materials similar to those described previously for the dielectric layer 136. The dielectric layer 136 and the dielectric layer 142 may be formed of the same material(s) or may be formed of different materials.

In some embodiments, a PPI 150 is formed over the dielectric layer 142. The PPI 150 may be electrically connected to the PPI 138 and thus to the devices 112. The PPI 150 may include conductive features such as redistribution lines, metal pads, Under-Bump Metallizations (UBMs), or the like. In accordance with some embodiments, a dielectric layer 152 may be formed over the PPI 150. The dielectric layer 152 may cover and/or encircle the conductive features of the PPI 150, and the dielectric layer 152 may physically contact a top surface of the dielectric layer 142. The dielectric layer 152 may be formed of one or more materials similar to those described previously for the dielectric layer 136, or may be formed of another material such as a molding compound, an encapsulant, or the like. Other materials are possible.

In accordance with some embodiments, conductive connectors 154 are formed on the PPI 150. The conductive connectors 154 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 154 may include a conductive material such as solder, copper, aluminum, gold, nickel, silver, palladium, tin, the like, or a combination thereof. In some embodiments, the conductive connectors 154 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 154 comprise metal pillars (such as a copper pillar) formed by sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. The conductive connectors 154 may be encircled or embedded in the dielectric layer 152, in some embodiments. The conductive connectors 154 may be formed before or after deposition of the dielectric layer 152. In some embodiments, a singulation process (e.g., a sawing process or the like) may be performed to singulate the structure into individual package components 100 that each comprise at least one capacitor 146. In some embodiments, the singulated package components 100 are device dies or the like. The singulation process may be performed before or after formation of the conductive connectors 154.

In accordance with some embodiments, the package component 100 includes one or more capacitors 146. As described previously, the capacitors 146 are represented in FIG. 1 by capacitors 146A, 146B, and/or 146C. The capacitors 146 may be formed in one or more dielectric layers of the package component 100, such as the dielectric layers 118 of the interconnect structure 116 or the dielectric layers 136/142. In this manner, the capacitors 146 may be formed as part of a MEOL process and/or a BEOL process. The capacitor 146A represents a capacitor 146 formed in an upper dielectric layer 118 of the interconnect structure 116, such as a dielectric layer 118 at or near the top of the interconnect structure 116. The capacitor 146A may be formed underneath the passivation layer 132, as shown in FIG. 1. The capacitor 146A is electrically coupled to the conductive pads 128, in some embodiments. The capacitor 146B represents a capacitor 146 formed in one or more dielectric layers 118 within the interconnect structure 116. For example, the capacitor 146B may be formed at or near the bottom or the middle of the interconnect structure 116. The capacitor 146B is electrically coupled to conductive lines 120 or vias 122 of the interconnect structure 116, in some embodiments. The capacitor 146C represents a capacitor 146 formed over the passivation layer 132, such as in the dielectric layer 136 and/or the dielectric layer 142. In some embodiments, the dielectric layer 136 and/or 142 may be a polymer layer, as described previously. The capacitor 146C is electrically coupled to the PPI 138 and/or the PPI 150, in some embodiments.

In some embodiments, a capacitor 146 is electrically coupled to other features of a package component by vias or contact plugs that physically and electrically contact the top electrode(s) and the bottom electrode(s) of the capacitor 146. In some embodiments, a capacitor 146 is a decoupling capacitor, in which the top electrode(s) and the bottom electrode(s) of the capacitor 146 are electrically coupled to power supply lines such as VDD and VSS. In this manner, a capacitor 146 may be used to filter or suppress power supply noise and/or may be used to reduce the effect of voltage variation from the power source. In accordance with alternative embodiments of the present disclosure, the top electrode(s) and the bottom electrode(s) of a capacitor 146 are connected to signal lines, and the capacitor 146 is used to filter or suppress signal line noise. In other embodiments, a capacitor 146 as described herein may be used in other structures or for other purposes. As a non-limiting example, a capacitor 146 may be used in Dynamic Random-Access Memory (DRAM) cells. Other structures or devices having capacitors 146 as described herein are possible.

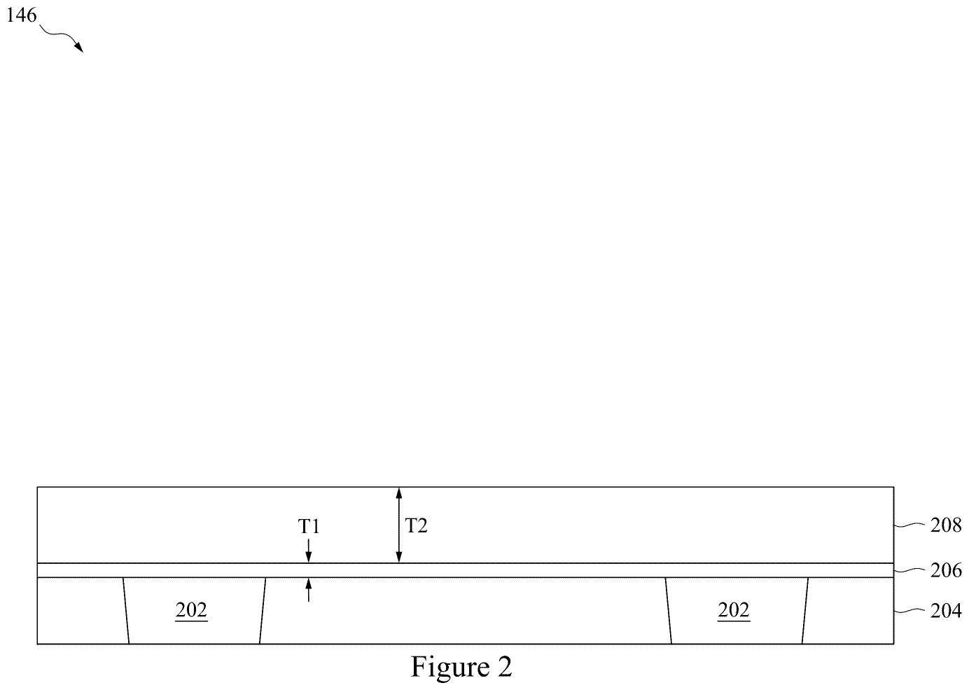

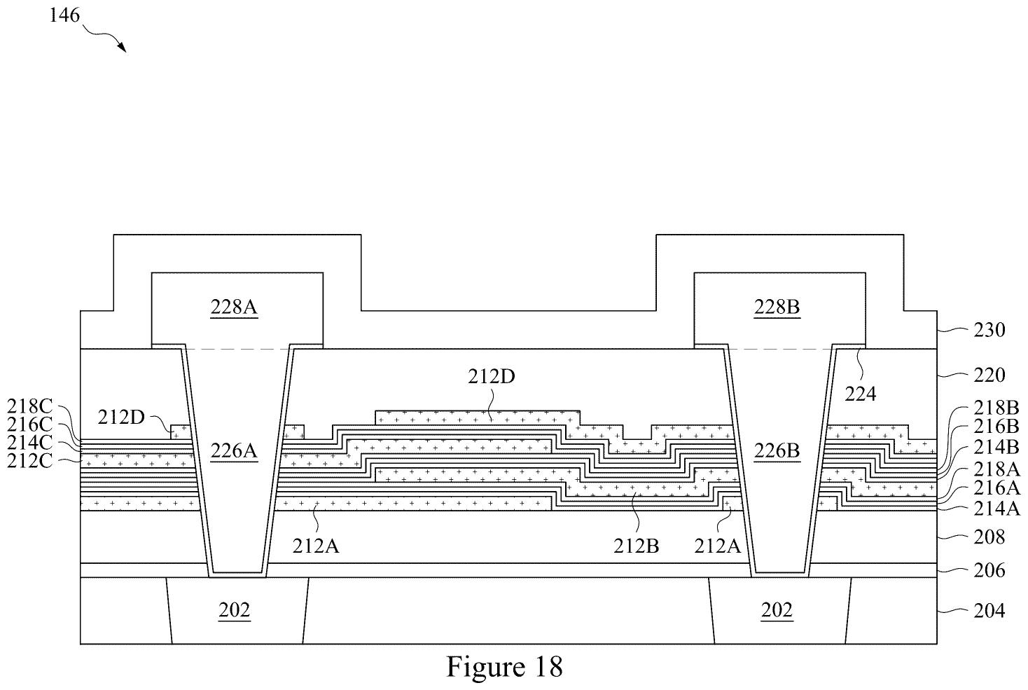

FIGS. 2 through 18 illustrate cross-sectional views of intermediate stages in the formation of a capacitor 146 (see FIG. 18), in accordance with some embodiments. The process of FIGS. 2-18 is shown in a context similar to that of forming a capacitor 146A of FIG. 1, but it should be appreciated that the techniques described herein may be applied to the formation of a capacitor 146B, a capacitor 146C, or other capacitors formed in other layers. In this manner, the cross-sectional views of FIGS. 2-18 may correspond to magnified views of a portion of the package component 100 of FIG. 1, such as a portion of the interconnect structure 116. The capacitor 146 shown in FIG. 18 comprises alternating layers of electrodes 212 (individually indicated as electrodes 212A, 212B, 212C, and 212D) and layers of insulators 216 (individually indicated as insulators 216A, 216B, and 216C). As used in the present disclosure, the term “electrode 212” may refer to any or all of the electrodes 212A-D, and the term “insulator 216” may refer to any or all of the insulators 216A-C. The electrodes 212A may be considered “bottom electrodes” and the electrodes 212D may be considered “top electrodes” in some cases. The insulator 216A may be considered a “bottom insulator” and the insulator 216C may be considered a “top insulator” in some cases. Each insulator 216 is separated from an underlying electrode 212 by a bottom barrier layer 214 (individually indicated as bottom barrier layers 214A, 214B, and 214C) and is separated from an overlying electrode 212 by a top barrier layer 218 (individually indicated as top barrier layers 218A, 218B, and 218C). The capacitor 146 shown in FIG. 18 is an example, and other capacitors 146 having a different configuration, a different layout, a different number of various layers (e.g., electrodes 212, bottom barrier layers 214, insulators 216, and/or top barrier layers 218), or a different arrangement of features are possible.

Referring to FIG. 2, conductive features 202 in a dielectric layer 204 are illustrated, in accordance with some embodiments. In some embodiments, the conductive features 202 may be similar to conductive features of the interconnect structure 116, such as conductive lines 120, vias 122, or conductive pads 128. In other embodiments, the conductive features 202 may be similar to other features, such as the metal pads 130, the PPI 138, the PPI 150, or the like. The conductive features 202 may be formed within a dielectric layer 204, which may be similar to a dielectric layer 118 of the interconnect structure 116, in some embodiments. For example, the dielectric layer 204 may comprise silicon oxide, silicon nitride, or the like. In other embodiments, the dielectric layer 204 may be similar to another dielectric layer, such as the dielectric layer 136, the dielectric layer 142, or the like. For example, in some embodiments, the dielectric layer 204 may comprise a polymer. Other materials are possible.

An etch stop layer 206 and a dielectric layer 208 are formed over the conductive features 202 and the dielectric layer 204, in accordance with some embodiments. The etch stop layer 206 is an optional layer, and may comprise one or more layers of dielectric material that have a lower etch rate than the underlying dielectric layer 204 and/or the overlying dielectric layer 208, in some cases. In some embodiments, the etch stop layer 206 may comprise one or more layers of material such as silicon nitride, silicon oxide, silicon oxynitride, silicon carbide, silicon carbonitride, silicon oxycarbide, the like, or a combination thereof. The etch stop layer 206 may be formed using a suitable technique, such as CVD, PECVD, LPCVD, PVD, ALD, or the like. Other materials or formation techniques are possible. In some embodiments, the etch stop layer 206 may have a thickness T1 in the range of about 700 Å and about 2,000 Å, though other thicknesses are possible.

The dielectric layer 208 may be formed of material(s) similar to those described previously for the dielectric layer 204, the dielectric layers 118, or the dielectric layers 136/142, and may be formed using similar techniques. For example, in some embodiments, the dielectric layer 208 comprises silicon nitride, silicon oxynitride, or the like. Other materials are possible. The dielectric layer 208 may be the same material as the underlying dielectric layer 204 or may be a different material. In some embodiments, the dielectric layer 208 may be deposited to an initial thickness T2 in the range of about 4 kÅ to about 10 kÅ, though other thicknesses are possible.

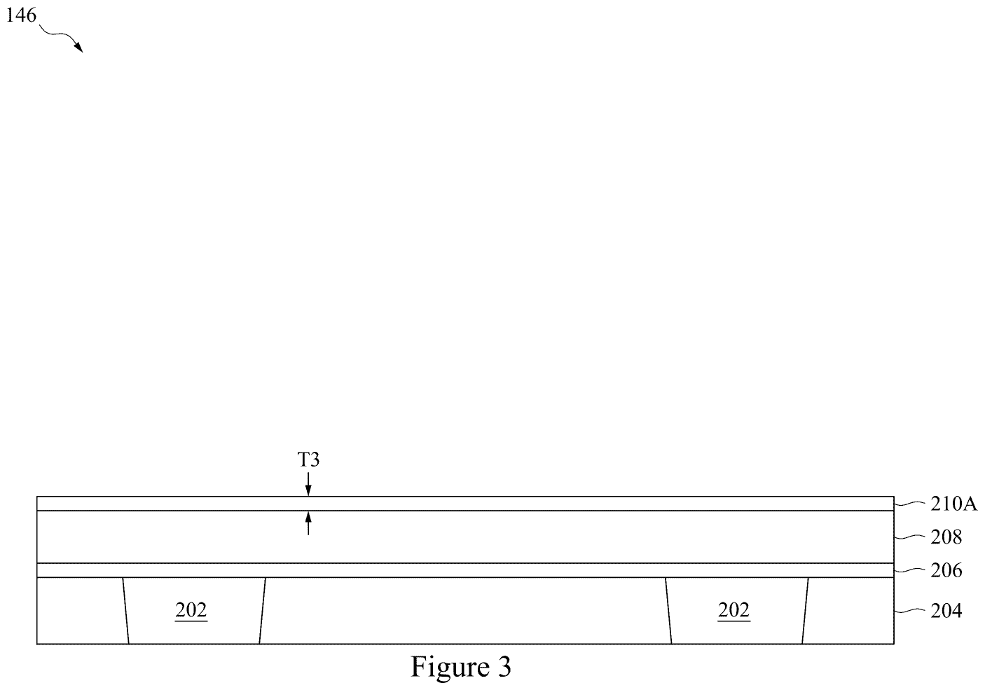

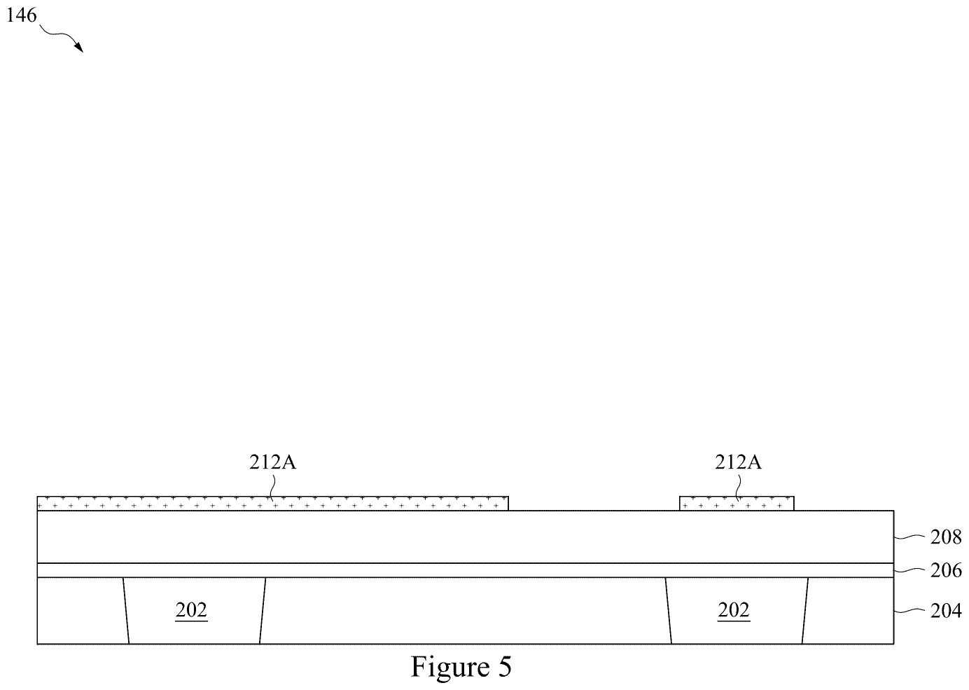

In FIG. 3, an electrode layer 210A is deposited over the dielectric layer 208, in accordance with some embodiments. The electrode layer 210A is subsequently patterned to form electrodes 212A (see FIG. 5) of a capacitor 146 (see FIG. 18). The electrode layer 210A may be formed of one or more conductive materials such as titanium nitride, tantalum nitride, another metal nitride, tungsten, platinum, iridium, ruthenium, ruthenium oxide (e.g., RuO₂), or the like. The electrode layer 210A may be deposited as a blanket layer, and may be deposited using a suitable technique such as CVD, PECVD, ALD, or the like. In some embodiments, the electrode layer 210A may have a thickness T3 in the range of about 150 Å to about 500 Å, though other thicknesses are possible. In some embodiments, before depositing the electrode layer 210A, the dielectric layer 208 is thinned using a planarization process such as a Chemical-Mechanical Polishing (CMP) process or the like.

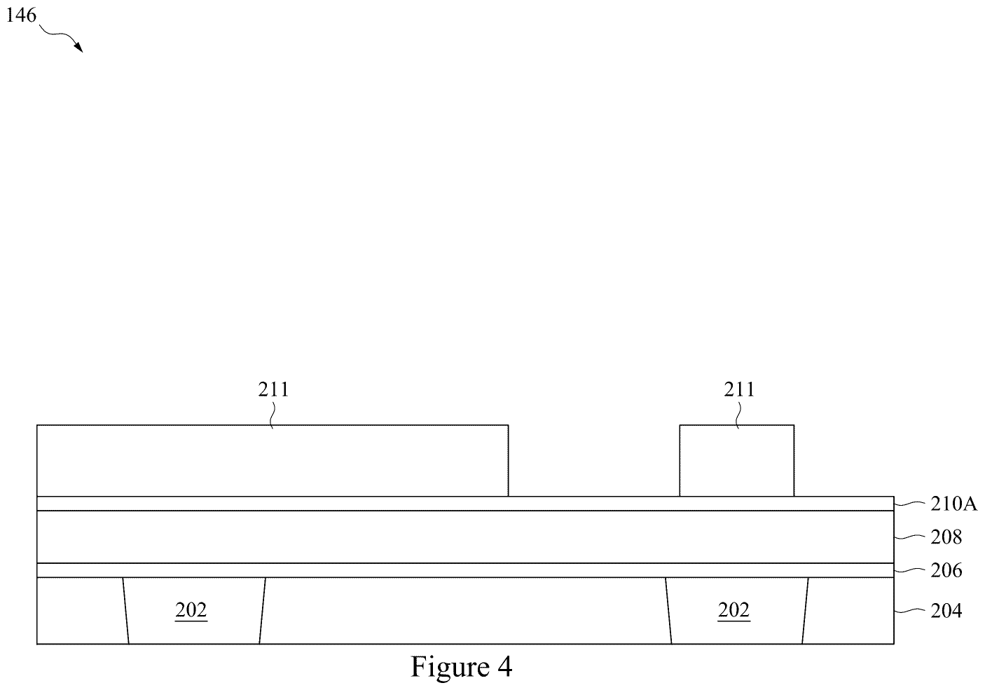

In FIG. 4, an etching mask 211 is formed over the electrode layer 210A, in accordance with some embodiments. The etching mask 211 may be formed by depositing a mask layer (not separately shown) over the electrode layer 210A and then patterning the mask layer to form the etching mask 211. The pattern of the etching mask 211 corresponds to the pattern of the subsequently formed electrodes 212A (see FIG. 5). The mask layer may be, for example, a photoresist, a multi-layer photoresist structure, a hard mask material, or the like. The mask layer may be formed using suitable techniques, such as using a spin-on technique. Other materials or techniques are possible. The mask layer may be patterned using suitable photolithographic techniques to form the etching mask 211.

In FIG. 5, the electrode layer 210A is etched using the etching mask 211 to form electrodes 212A, in accordance with some embodiments. The electrodes 212A may be the bottom-most electrodes of the capacitor 146 and may be considered “bottom electrodes” or “first electrodes” in some cases. In other embodiments, a single electrode 212A or another number of electrodes 212A may be formed. In some embodiments, an electrode 212A may be separated or otherwise electrically isolated from another electrode 212A. The electrode layer 210A may be etched using any acceptable etching process, such as a wet etching process, a dry etching process, a reactive ion etch (RIE), neutral beam etch (NBE), the like, or a combination thereof. The etching may be anisotropic. The etching may stop on the dielectric layer 208, in some embodiments. In accordance with some embodiments, the etching is performed using a dry etching process comprising one or more chlorine-based gases such as TiClₓ, TaClₓ, WClₓ, chlorine (Cl₂), or the like. In some embodiments, a process gas of the dry etching process may comprise one or more fluorine-containing gases such as CHF₃, CF₄, or the like. In some embodiments, a process gas of the dry etching process may include oxygen (O₂). In accordance with some embodiments, the dry etching process comprises a process pressure in the range of about 5 mTorr to about 10 mTorr. The flow rate of the process gas(es) may be in the range of about 20 sccm to about 800 sccm. The source power (used to generate plasma) may be in the range of about 1,000 Watts to about 1,500 Watts. The bias power may be in the range of about 80 Watts to about 100 Watts. Other process gases or other process parameters are possible. In accordance with alternative embodiments, the etching is performed through a wet etching process. The wet etching process may comprise a wet etchant comprising NH₄OH (e.g., ammonia water), H₂O₂, H₂O, the like, or a combination thereof. Other wet etchants are possible. After patterning the electrode layer 210A to form the electrodes 212A, the etching mask 211 may be removed using an acceptable process, such as an ashing process or the like.

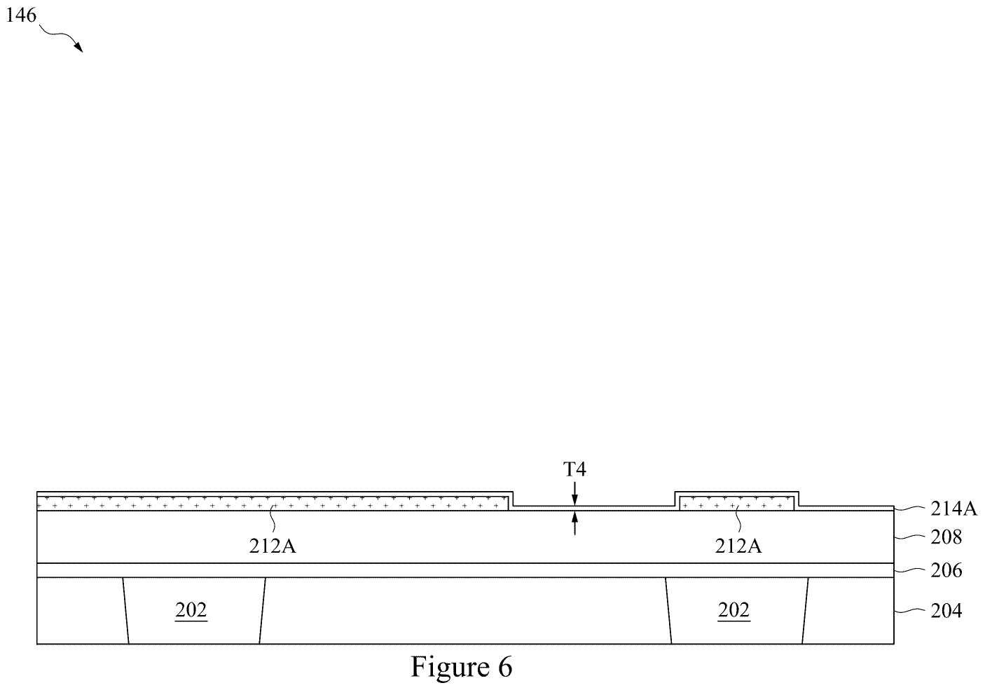

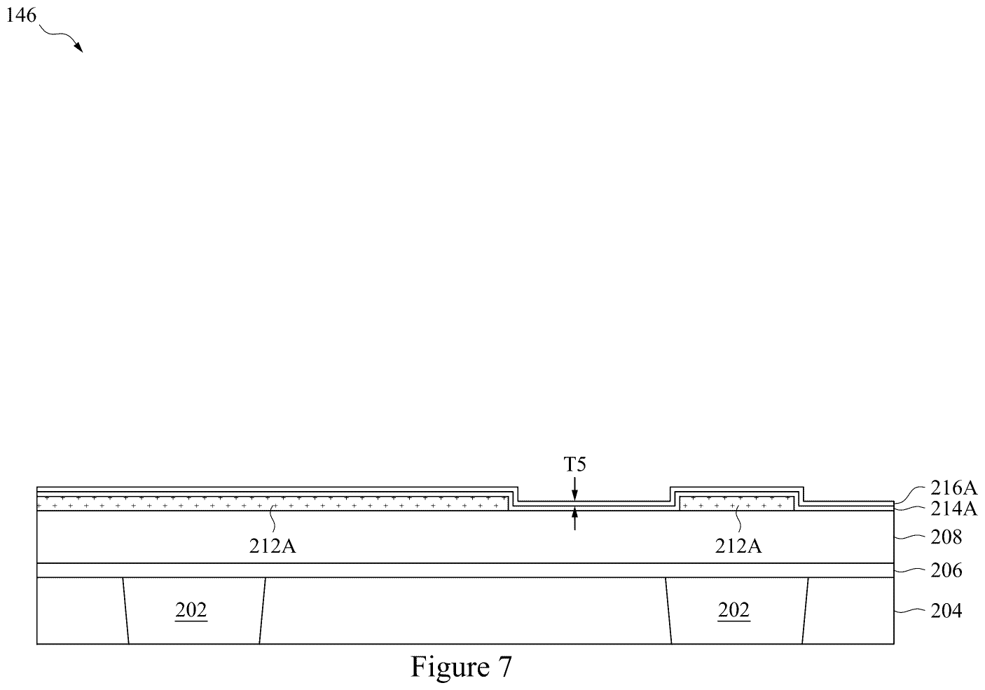

In FIG. 6, a bottom barrier layer 214A is deposited over the electrodes 212A and the dielectric layer 208, in accordance with some embodiments. A bottom barrier layer 214 (e.g., bottom barrier layer 214A) may be formed between an electrode 212 (e.g., electrodes 212A) and an overlying insulator 216 (e.g., insulator 216A, see FIG. 7) to block or reduce diffusion of oxygen from the overlying insulator 216 into the electrode 212. In this manner, in some cases a bottom barrier layer 214 may be considered a “diffusion barrier layer,” an “oxygen-blocking layer,” or the like. In some cases, reducing the diffusion of oxygen into electrodes 212 by forming bottom barrier layers 214 as described herein can reduce leakage in capacitors 146 and can improve reliability, improve lifetime, and/or improve uniformity of capacitors 146.

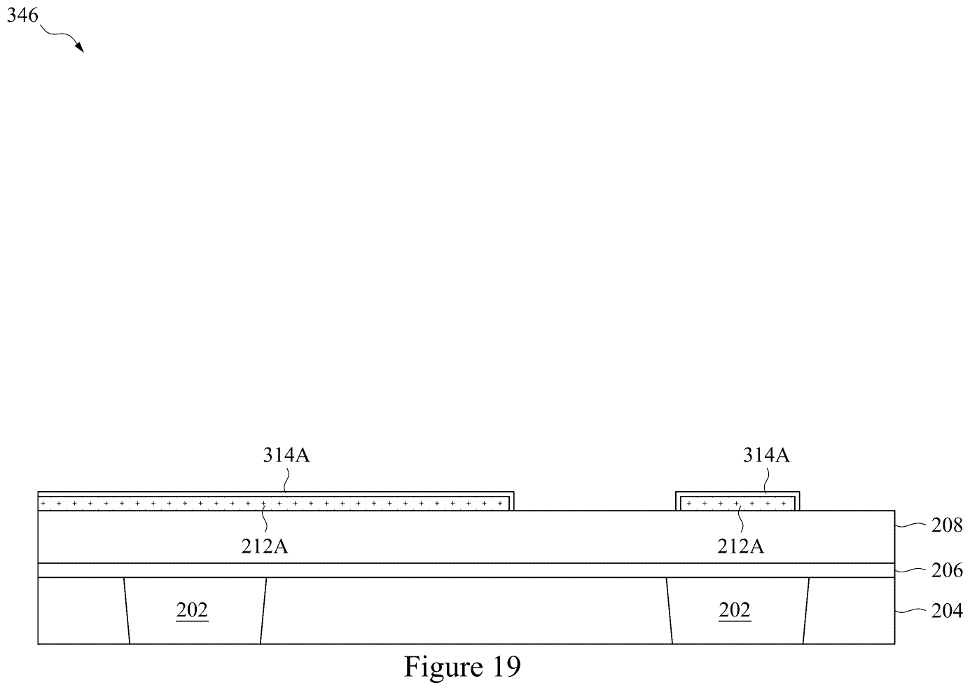

In some embodiments, the bottom barrier layer 214A is formed of a material such as titanium oxide (e.g., TiO₂), titanium oxynitride (e.g., TiON), aluminum oxide (e.g., Al₂O₃), another metal oxide, the like, a combination thereof, or multilayers thereof. In some embodiments, the bottom barrier layer 214A is conformally deposited using a suitable technique such as ALD, PEALD, thermal ALD, or the like. In other embodiments, the bottom barrier layer 214A is formed using an oxidation process, and an example embodiment is described below for FIGS. 19-25. In some embodiments in which the bottom barrier layer 214A is titanium oxide deposited using a PEALD process, the precursors may include tetrakis (dimethylamino) titanium (TDMAT) and an oxygen plasma. The PEALD process may comprise a process temperature in the range of about 160° C. to about 300° C. In some embodiments in which the bottom barrier layer 214A is titanium oxide deposited using a thermal ALD process, the precursors may include TiCl₄ and H₂O. The thermal ALD process may comprise a process temperature in the range of about 150° C. to about 300° C. These are examples, and other materials, precursors, process parameters, or deposition techniques are possible. In some embodiments, the bottom barrier layer 214A may have a thickness T4 in the range of about 5 Å to about 30 Å, though other thicknesses are possible.

FIG. 7 illustrates the formation of an insulator 216A over the bottom barrier layer 214A, in accordance with some embodiments. The insulator 216A may comprise one or more materials having a high dielectric constant (e.g., high-k) to achieve larger capacitance values of the resulting capacitor 146. For example, in some embodiments, the insulator 216A may comprise hafnium oxide (e.g., HfO₂), zirconium oxide (e.g., ZrO₂, ZrO₃, or the like), hafnium zirconium oxide (e.g., HfZrO), aluminum oxide (e.g., Al₂O₃), the like, a combination thereof, or multilayers thereof. The insulator 216A may be deposited as a conformal layer using a suitable technique, such as ALD or the like. In some embodiments, the insulator 216A may be deposited using ZrCl₄ as a zirconium-supplying precursor, HfCl₄ as a hafnium-supplying precursor, trimethylaluminum (TMA) as an aluminum-supplying precursor, and/or H₂O (e.g., water steam or water vapor) as an oxygen-supplying precursor. In some embodiments, the insulator 216A may be deposited using a process pressure in the range of about 0.1 Torr to about 100 Torr, and a process temperature in the range of about 220° C. and about 330° C. Other materials, precursors, or process parameters are possible. In some embodiments, the insulator 216A may have a thickness T5 in the range of about 30 Å to about 100 Å, though other thicknesses are possible.

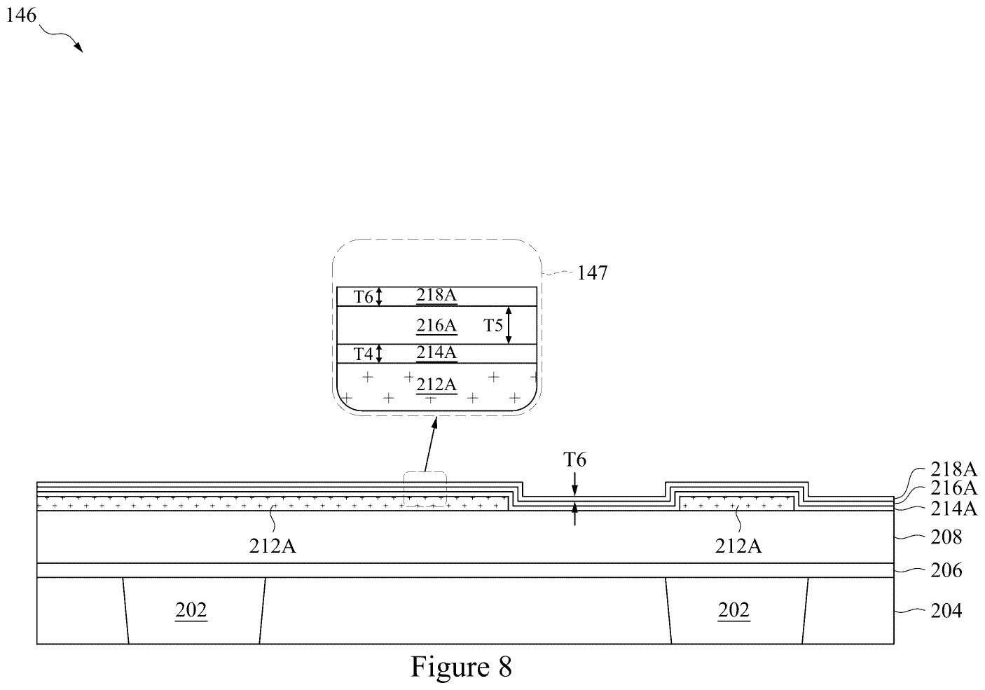

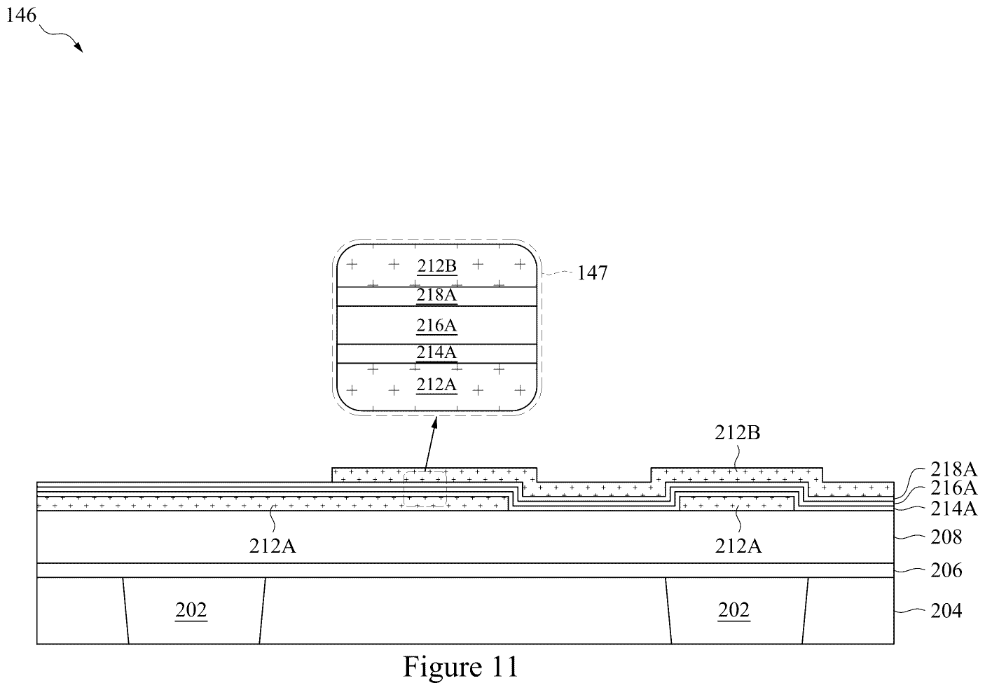

In FIG. 8, a top barrier layer 218A is deposited over the insulator 216A, in accordance with some embodiments. FIG. 8 also illustrates a magnified view 147 of a portion of the structure. A top barrier layer 218 (e.g., top barrier layer 218A) may be formed between an insulator 216 (e.g., insulator 216A) and an overlying electrode 212 (e.g., electrode 212B, see FIG. 11) to block or reduce diffusion of oxygen from the insulator 216 into the overlying electrode 212. Similar to a bottom barrier layer 214, the use of a top barrier layer 218 as described herein can reduce leakage in capacitors 146 and can improve reliability, improve lifetime, and/or improve uniformity of capacitors 146. Additionally, the use of both a bottom barrier layer 214 and a top barrier layer 218 as described herein can further improve the reliability and lifetime of capacitors 146, described in greater detail below.

In some embodiments, the top barrier layer 218A is formed of one or more materials such as titanium oxide (e.g., TiO₂), titanium oxynitride (e.g., TiON), aluminum oxide (e.g., Al₂O₃), zirconium oxide (e.g., ZrO₂), another metal oxide, the like, a combination thereof, or multilayers thereof. In some embodiments, the top barrier layer 218A is conformally deposited using a suitable technique such as ALD, PEALD, thermal ALD, or the like. In some embodiments, the top barrier layer 218 comprises titanium oxide deposited using a technique similar to those described previously for the bottom barrier layer 214A. The top barrier layer 218A may be a material that is similar to or different than the bottom barrier layer 214A. Other materials are possible. In some embodiments, the top barrier layer 218A may have a thickness T6 in the range of about 5 Å to about 30 Å, though other thicknesses are possible. The thickness T6 of the top barrier layer 218A may be smaller than, about the same as, or greater than the thickness T4 of the bottom barrier layer 214A.

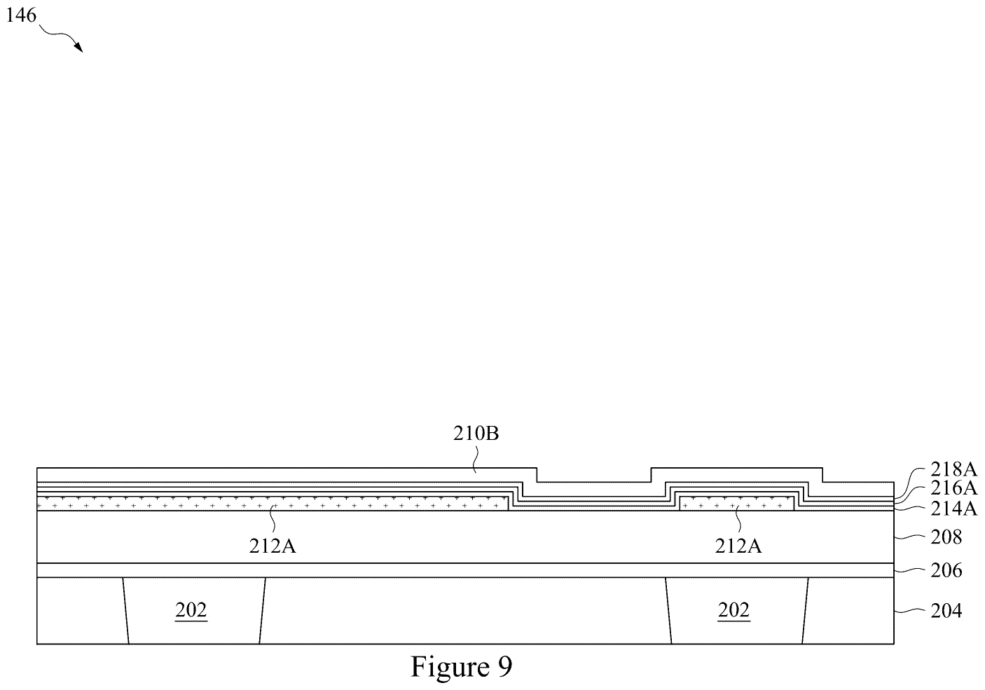

In FIG. 9, an electrode layer 210B is deposited over the top barrier layer 218A, in accordance with some embodiments. The electrode layer 210B is subsequently patterned to form electrodes 212B (see FIG. 11) of a capacitor 146 (see FIG. 18). The electrode layer 210B may be similar to the electrode layer 210A described previously for FIG. 3, and may be formed using similar techniques. The electrode layer 210B may have a thickness that is smaller than, about the same as, or greater than the thickness T3 of the electrode layer 210A (see FIG. 3).

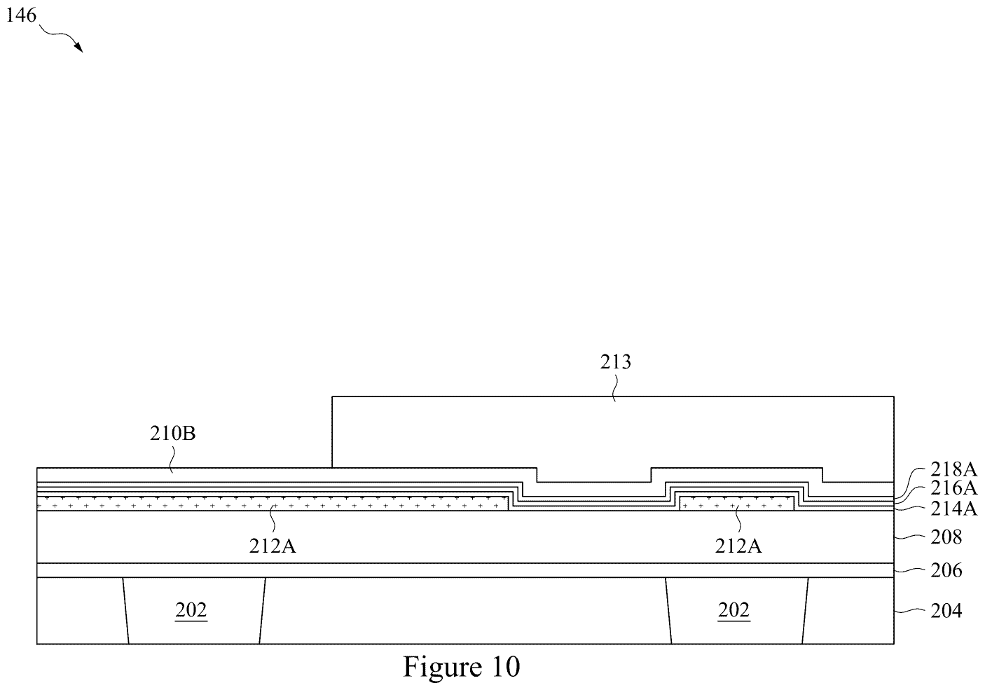

In FIG. 10, an etching mask 213 is formed over the electrode layer 210B and patterned, in accordance with some embodiments. The etching mask 213 may be similar to the etching mask 211 described previously for FIG. 4, and may be patterned using similar techniques. For example, a mask layer may be deposited over the electrode layer 210B and patterned using suitable photolithographic techniques to form the etching mask 213. The pattern of the etching mask 213 corresponds to the pattern of the subsequently formed electrodes 212B (see FIG. 11).

In FIG. 11, the electrode layer 210B is etched using the etching mask 213 to form electrode 212B, in accordance with some embodiments. FIG. 11 also shows a magnified view 147 of a portion of the structure, similar to FIG. 8. The electrode 212B is opposite the insulator 216A from the electrodes 212A, and the electrode 212B may be considered a “top electrode” or a “second electrode,” in some cases. More than one electrode 212B may be formed, in other embodiments. The electrode layer 210B may be etched using any acceptable etching process, such as those described previously for etching the electrode layer 210A. The etching may be anisotropic. The etching may stop on the top barrier layer 218A, in some embodiments.

In some cases, a barrier layer of a capacitor may be a material that can trap electrons, such as titanium oxide. In these cases, the barrier layer may have a concentration of trapped electrons at or near the side of the barrier layer that is closest to the positively biased electrode (e.g., with the other electrode being less positively biased, grounded, or negatively biased). For example, the concentration of trapped electrons within the barrier layer may be near the neighboring electrode if the neighboring electrode is positively biased, or the concentration of trapped electrons within the barrier layer may be near the insulator if the electrode opposite the insulator is positively biased.

For a capacitor having a single barrier layer, a concentration of trapped electrons near the insulator can result in a stronger electric field within the insulator than when the concentration of trapped electrons is farther from the insulator (e.g., near the neighboring electrode). This effect is at least partly due to the electric field being concentrated in the insulator when the trapped electrons are near the insulator, whereas the electric field is spread across both the insulator and the barrier layer when the trapped electrons are near the neighboring electrode.

As an illustrative example, FIGS. 27A-27B show a portion of a capacitor 400 having a first electrode 412A, a barrier layer 414 having trapped electrons 415, an insulator 416, and a second electrode 412B. FIG. 27A shows the capacitor 400 under a “forward bias” in which the first electrode 412A is more negatively biased and the second electrode 412B is more positively biased. As shown in FIG. 27A, this biasing results in the trapped electrons 415 being concentrated near the insulator 416. The electric field EA between the electrodes 412A-B extends from the second electrode 412B into the insulator 416 and terminates (or partially terminates) at the trapped electrons 415. Thus, most or all of the electric field EA is within the insulator 416.

FIG. 27B shows the capacitor 400 under a “reverse bias” in which the first electrode 412A is more positively biased and the second electrode 412B is more negatively biased. As shown in FIG. 27B, this biasing results in the trapped electrons 415 being concentrated near the second electrode 412A. The electric field EB between the electrodes 412A-B extends from the trapped electrons 415 (and/or the first electrode 412A) into the insulator 416 and terminates at the second electrode 412B. Thus, all of the electric field EB is within both the barrier layer 414 and the insulator 416. In this manner, the electric field EB is spread over a larger distance than the electric field EA. Thus, for the same voltage difference between electrodes 412A-B, the insulator 416 of the reverse-biased capacitor 400 of FIG. 27B experiences a smaller electric field than the insulator 416 of the forward-biased capacitor 400 of FIG. 27A.

In this manner, for a capacitor having a single barrier layer, biasing the capacitor in one direction (e.g., “forward biased”) can generate higher electric fields in the insulator than biasing the capacitor in the opposite direction (e.g., “reverse biased”). An insulator experiencing a larger electric field during operation can have a greater defect generation rate, an increased chance of leakage, a smaller breakdown voltage, and/or a reduced lifetime (e.g., Time-Dependent Dielectric Breakdown (TDDB) lifetime). This increased electric field in the insulator due to electron trapping in the barrier layer can result in a capacitor lifetime that is strongly dependent on bias polarity. For example, in some cases, the lifetime of a capacitor can that is reverse-biased be greater than 10000 times longer than the lifetime of a similar capacitor that is forward-biased.

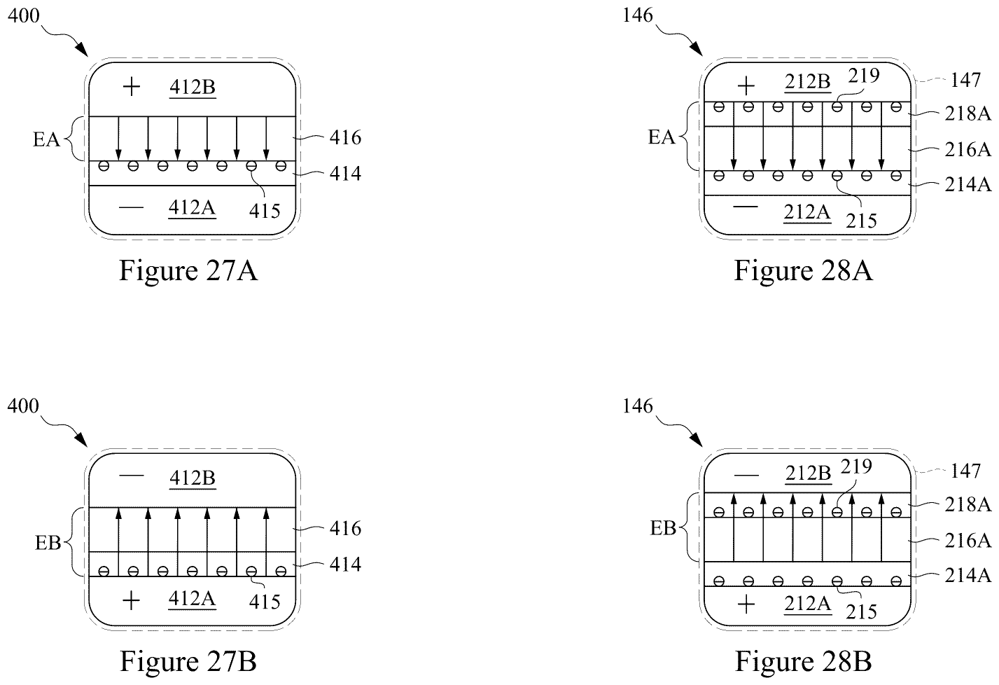

The use of a symmetric barrier layer/insulator/barrier layer structure as described herein can reduce the effect of electron trapping in barrier layers. As an illustrative example, FIGS. 28A-28B show a magnified view 147 of a capacitor 146, similar to the magnified view 147 shown in FIG. 11. FIG. 28A shows the capacitor 146 under a “forward bias” in which the electrode 212A is more negatively biased and the electrode 212B is more positively biased. As shown in FIG. 28A, this biasing results in the trapped electrons 215 in the bottom barrier layer 214A being concentrated near the insulator 216A and the trapped electrons 219 in the top barrier layer 218A being concentrated near the electrode 212B. The electric field EA between the electrodes 212A-B extends from the trapped electrons 219 (and/or the electrode 212B) into the insulator 216 and terminates (or partially terminates) at the trapped electrons 215. Thus, most or all of the electric field EA is within both the top barrier layer 218A and the insulator 216A.

FIG. 28B shows the capacitor 146 under a “reverse bias” in which the electrode 212A is more positively biased and the electrode 212B is more negatively biased. As shown in FIG. 28B, this biasing results in the trapped electrons 215 in the bottom barrier layer 214A being concentrated near the electrode 212A and the trapped electrons 219 in the top barrier layer 218A being concentrated near the insulator 216A. The electric field EB between the electrodes 212A-B extends from the trapped electrons 215 (and/or the electrode 212A) into the insulator 216 and terminates (or partially terminates) at the trapped electrons 219. Thus, most or all of the electric field EB is within both the bottom barrier layer 214A and the insulator 216A.

As shown in FIGS. 28A-28B, for either bias polarity, the electric field (e.g., EA or EB) extends across the insulator 216A and into one of the barrier layers 214A/218A. This allows the presence of one of the barrier layers 214A/218A to compensate for electron trapping effects of the other, and can allow the distance of the electric field to be the same or similar for either bias polarity, in some cases. In this manner, by sandwiching the insulator 216 between the two barrier layers 214A/218A, the electric field across the insulator 216A does not significantly increase for a particular bias polarity. In other words, forming a top barrier layer 218A in addition to a bottom barrier layer 214A can reduce the electric field across the insulator 216A when the capacitor 146 is forward biased. By reducing the electric field across the insulator 216 for both bias polarities, the capacitor 146 may have a smaller defect generation rate, an reduced chance of leakage, a greater breakdown voltage, and/or an increased lifetime (e.g., TDDB lifetime or Time-To-Fail (TTF) lifetime). In some cases, the use of the techniques described herein can increase the lifetime of a capacitor by about 100 times or greater.

Additionally, the effects of electron trapping on electric field strength are reduced for either bias polarity, which can give the capacitor 146 a more uniform capacitance across different voltage biases of either polarity. In some embodiments, the addition of a second barrier layer as described herein may not significantly affect the capacitance of a capacitor in either bias polarity. For example, the addition of a second barrier layer may decrease the capacitance of a capacitor by less than about 10%, in some cases.

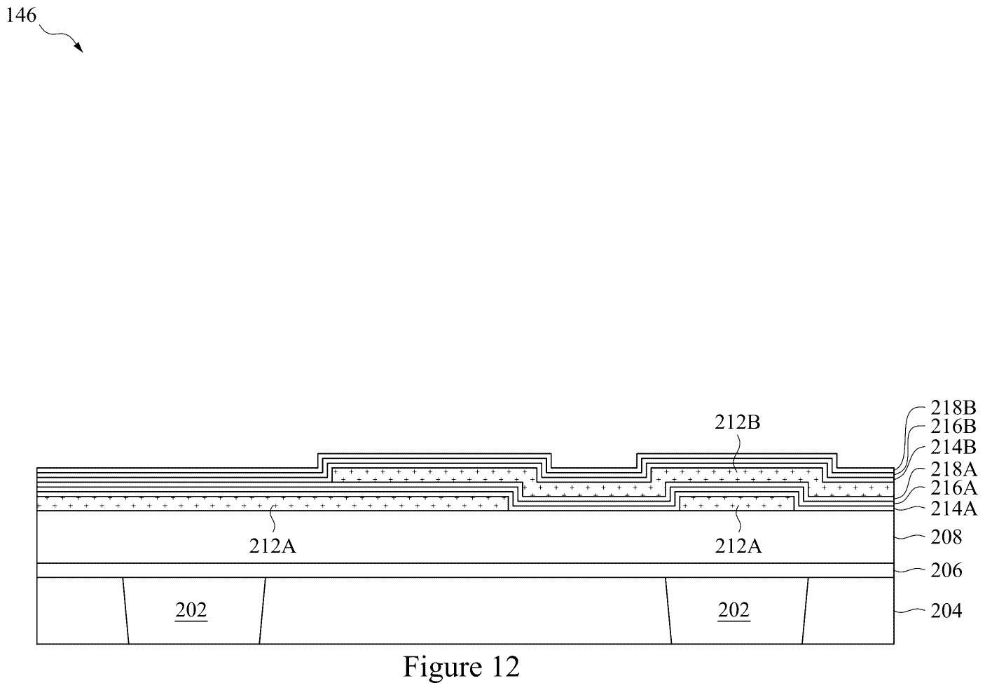

Turning now to FIG. 12, a bottom barrier layer 214B, an insulator 216B, and a top barrier layer 218B are formed over the electrode 212B, in accordance with some embodiments. The layers 214B/216B/218B may also be formed over exposed portions of the top barrier layer 218A, as shown in FIG. 12. The bottom barrier layer 214B, the insulator 216B, and/or the top barrier layer 218B may be formed using materials or techniques similar to those described previously for the bottom barrier layer 214A, the insulator 216A, and the top barrier layer 218A, respectively. For example, in some embodiments, the layers 214B/216B/218B may be blanket layers deposited using ALD, PEALD, thermal ALD, or the like. Other materials or techniques are possible. In some embodiments, the bottom barrier layer 214B, the insulator 216B, and/or the top barrier layer 218B have thicknesses similar to those of the bottom barrier layer 214A, the insulator 216A, and/or the top barrier layer 218A, respectively. Other thicknesses are possible. In other embodiments, no additional bottom barrier layers, insulators, top barrier layers, or electrodes are formed over the electrode 212B for the formation of the capacitor 146.

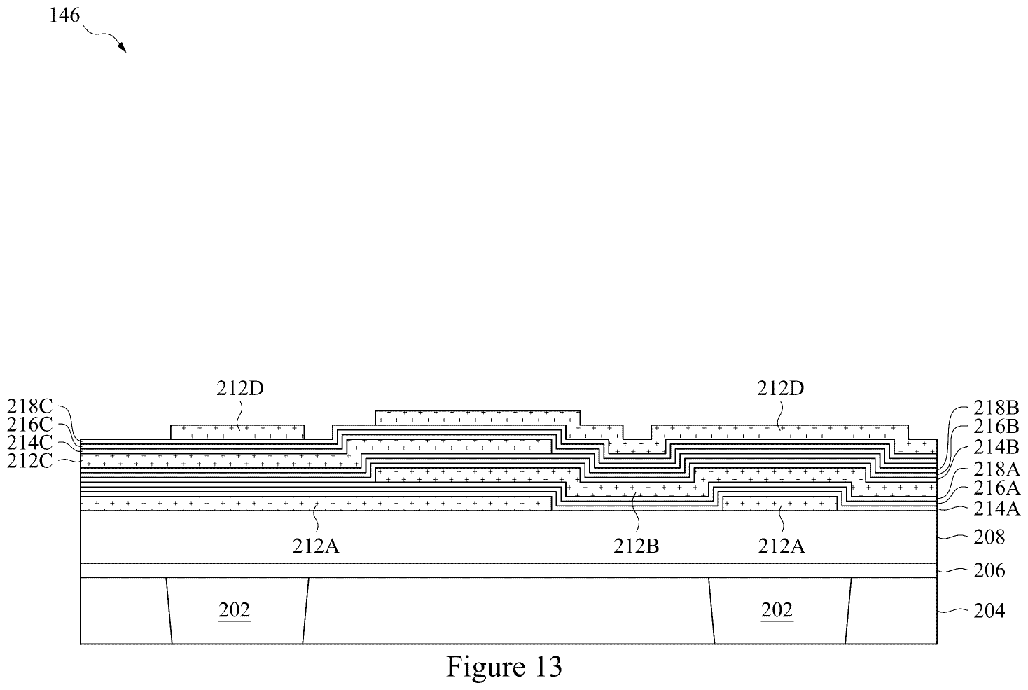

FIG. 13 illustrates the formation of an electrode 212C, a bottom barrier layer 214C, an insulator 216C, a top barrier layer 218C, and electrodes 212D, in accordance with some embodiments. The electrodes 212C-D and the layers 214C/216C/218C may be formed using materials or techniques similar to those described previously for the electrodes 212A and the layers 214A/216A/218A, respectively. For example, the electrode 212C may be formed by depositing an electrode layer over the top barrier layer 218B and then patterning the electrode layer. The electrode 212C may be considered a “third electrode,” in some cases. The bottom barrier layer 214C, the insulator 216C, and the top barrier layer 218C may then be deposited over the electrode 212C and over exposed portions of the top barrier layer 218B. The electrodes 212D may be formed by depositing an electrode layer over the top barrier layer 218C and then patterning the electrode layer. The electrodes 212D may be the top-most electrodes of the capacitor 146 and may be considered “top electrodes” or “fourth electrodes” in some cases. In other embodiments, a single electrode 212D or another number of electrodes 212D may be formed. In some embodiments, an electrode 212D may be separated or otherwise electrically isolated from another electrode 212D. In other embodiments, one or more additional bottom barrier layers, insulators, top barrier layers, and/or electrodes may be formed over the electrodes 212D for the formation of the capacitor 146.

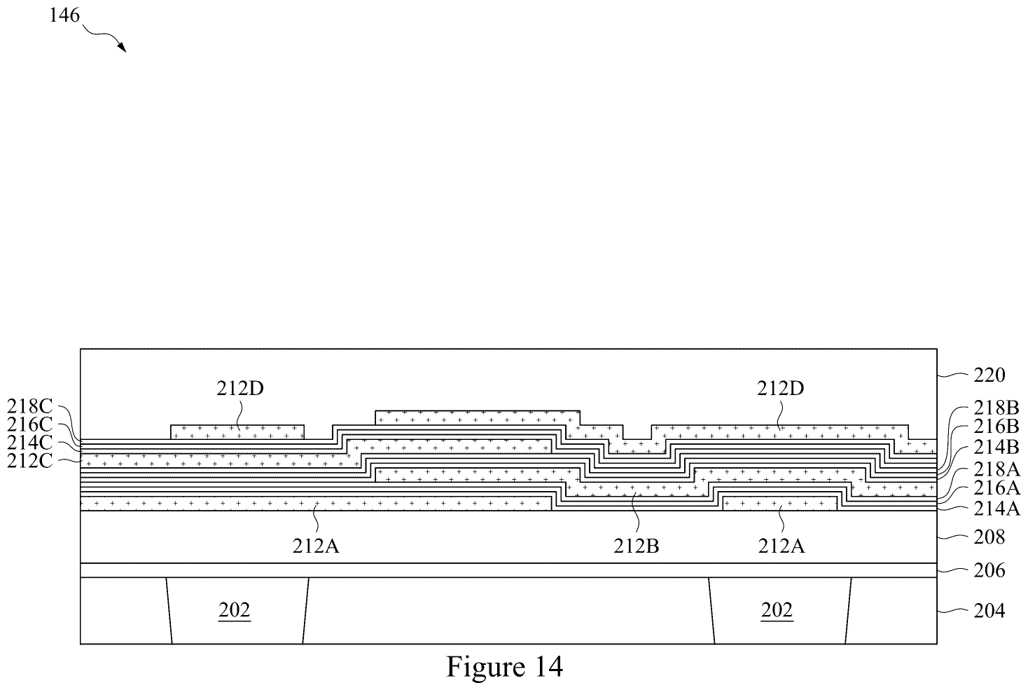

In FIG. 14, a dielectric layer 220 is deposited over the electrodes 212D and the top barrier layer 218C, in accordance with some embodiments. The dielectric layer 220 may be formed of material(s) similar to those described previously for the dielectric layer 204, the dielectric layers 118, or the dielectric layers 136/142, and may be formed using similar techniques. For example, in some embodiments, the dielectric layer 220 comprises silicon nitride, silicon oxynitride, a polymer, or the like. Other materials are possible. The dielectric layer 220 may be the same material as the dielectric layer 208 or may be a different material. In some embodiments, a planarization process, such as a CMP process or a grinding process, is performed on the dielectric layer 220. In some embodiments, the dielectric layer 220 has a thickness in the range of about 5 kÅ to about 10 kÅ, though other thicknesses are possible.

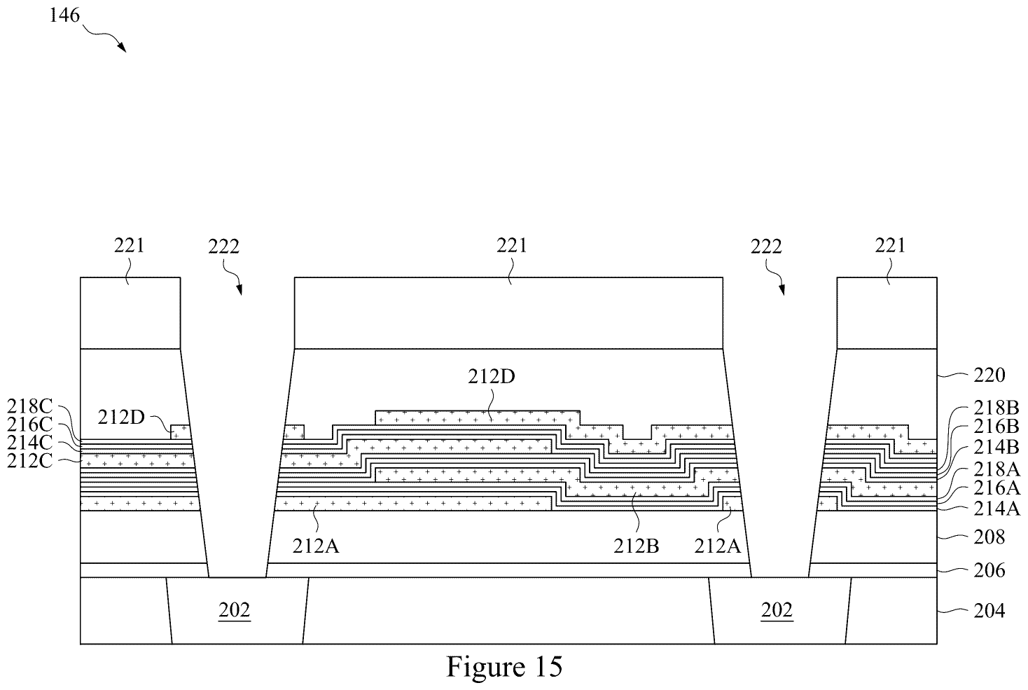

FIGS. 15, 16, and 17 illustrate cross-sectional views of intermediate steps in the formation of contact plugs 226A-B and conductive lines 228A-B, in accordance with some embodiments. In FIG. 15, contact openings 222 are formed to expose surfaces of the electrodes 212A-D and surfaces of the conductive features 202, in accordance with some embodiments. In other embodiments, the openings 222 may only expose surfaces of the electrodes 212A-D without exposing surfaces of the conductive features 202. The openings 222 may be formed, for example, by performing one or more etching processes using an etching mask 221. The etching mask 221 may be formed using techniques similar to those described previously for the etching mask 211 (see FIG. 4) or the etching mask 213 (see FIG. 10), in some embodiments. For example, the etching mask 221 may be formed by forming photoresist structure over the dielectric layer 220 and then patterning the photoresist structure using suitable photolithography techniques. In accordance with some embodiments, the etching mask 221 comprises a photoresist or photoresist structure, which may include an anti-reflective coating. The etching mask 221 may have a single-layer structure, a dual-layer structure, a tri-layer structure, or the like.

One or more etching processes may then be performed, using the etching mask 221, to form openings 222 extending through the dielectric layer 220, the electrodes 212A-D, the top barrier layers 218A-C, the insulators 216A-C, and the bottom barrier layers 214A-C. The openings 222 may also extend through the dielectric layer 208 and the etch stop layer 206, in some embodiments. The one or more etching processes may include wet etching processes and/or dry etching processes. One or more of the etching processes may be anisotropic. Different etching processes may be used to etch different materials, in some cases. For example, an etching process similar to that described previously for etching the electrode layer 210A may be used for etching the electrodes 212A-D. In some embodiments, a first dry etching process may be performed that stops on the etch stop layer 206, and a second dry etching process may then be performed to etch the etch stop layer 206 and expose the conductive features 202. This is an example, and other techniques or etching processes may be used for forming the openings 222 in other embodiments. After etching the openings 222, the etching mask 221 may be removed using a suitable process, such as an ashing process or an etching process.

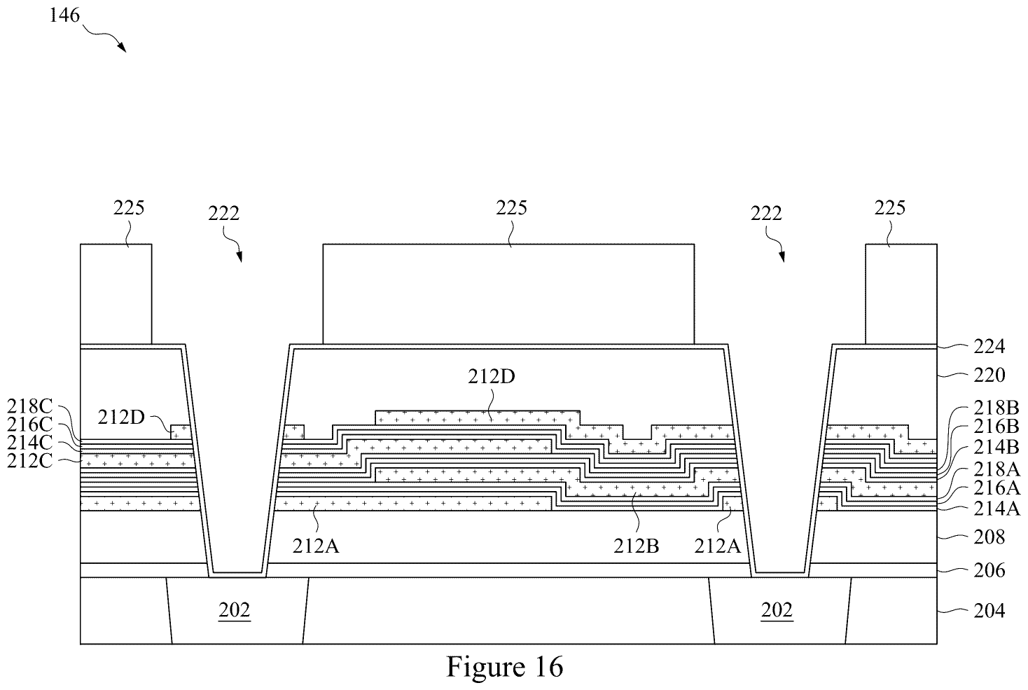

In FIG. 16, a seed layer 224 and a plating mask 225 are formed, in accordance with some embodiments. The seed layer 224 is formed over the dielectric layer 220 and in the openings 222. The seed layer 224 may make physical and electrical contact with surfaces of the electrodes 212A-D and/or the conductive features 202. In some embodiments, the seed layer 224 is a metal layer, which may be a single layer or a composite layer comprising a plurality of sub-layers formed of different materials. In some embodiments, the seed layer 224 comprises a titanium layer and a copper layer over the titanium layer, though other materials are possible. The seed layer 224 may be formed using, for example, PVD, CVD, Metal Organic Chemical Vapor Deposition (MOCVD), or the like. The plating mask 225 is then formed and patterned on the seed layer 224. The plating mask 225 may be similar to one or more of the etching masks 211, 213, or 221 described previously. For example, the plating mask 225 may be a photoresist, in some embodiments. The plating mask 225 may be patterned using suitable photolithography techniques. The pattern of the plating mask 225 may expose the seed layer 224 in and around the openings 222, in some embodiments.

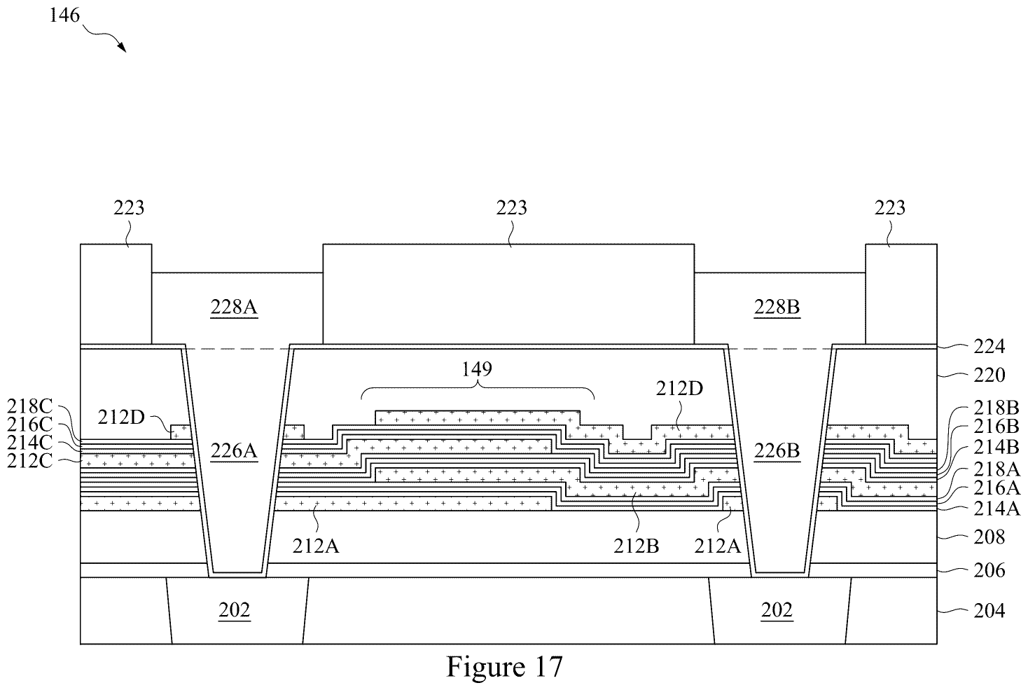

In FIG. 17, conductive material is deposited in the openings 222 to form the contact plugs 226A-B and the conductive lines 228A-B, in accordance with some embodiments. The conductive material may be formed in the openings 222 on the exposed portions of the seed layer 224. The conductive material may be formed by plating, such as electroplating or electroless plating, or the like. The conductive material may comprise a metal, like copper, titanium, nickel, tungsten, aluminum, alloys thereof, or the like. The combination of the conductive material and underlying portions of the seed layer 224 form the contact plugs 226A-B and the conductive lines 228A-B. The portions of the conductive material and seed layer 224 below a top surface of the dielectric layer 220 may be considered the contact plugs 226A-B, with the portions of the conductive material and seed layer 224 above or along the top surface of the dielectric layer 220 being considered the conductive lines 228A-B. The contact plug 226A and the conductive line 228A may be part of a continuous conductive feature, and the contact plug 226B and the conductive line 228B may be part of another continuous conductive feature, in some embodiments. In some embodiments, the conductive lines 228A-B may be similar to conductive features of the interconnect structure 116, such as conductive lines 120, vias 122, or conductive pads 128. In other embodiments, the conductive lines 228A-B may be similar to other features, such as the metal pads 130, the PPI 138, the PPI 150, or the like.

The contact plugs 226A-B may physically and electrically contact the conductive features 202, and the contact plugs 226A-B may be considered vias in some cases. The contact plugs 226A-B also physically and electrically contact the electrodes 212A-D. For example, the contact plug 226B contacts an electrode 212A, the electrode 212B, and an electrode 212D, and the contact plug 226A contacts an electrode 212A, the electrode 212C, and an electrode 212D. Accordingly, the capacitor 146 is formed, which includes a first set of electrodes 212A, 212B, and 212D collectively as a first capacitor electrode and a second set of electrodes 212A, 212C, and 212D as a second capacitor electrode. In some cases, most of the capacitance of the capacitor 146 is provided by the capacitive region 149 within which the first set of electrodes is interdigitated with (e.g. alternates with) the second set of electrodes. In this manner, the capacitive region 149 may include a stack of electrodes 212, in which each electrode 212 is respectively separated from each neighboring electrode 212 by a bottom barrier layer 214, an insulator 216, and a top barrier layer 218.

In FIG. 18, the plating mask 225 is removed and an optional passivation layer 230 is formed, in accordance with some embodiments. The plating mask 225 and underlying portions of the seed layer 224 may be removed using, for example, an ashing process and/or an etching process. The passivation layer 230 may then be deposited over the dielectric layer 220 and the conductive lines 228A-B, in accordance with some embodiments. The passivation layer 230 may be formed of material(s) similar to those described previously for the dielectric layer 220, dielectric layer 204, the dielectric layers 118, or the dielectric layers 136/142, and may be formed using similar techniques. For example, in some embodiments, the passivation layer 230 comprises silicon oxide, silicon nitride, silicon oxynitride, silicon oxycarbide, a polymer, the like, or a combination thereof. Other materials are possible. The passivation layer 230 may be the same material as the dielectric layer 220 or may be a different material. In some embodiments, the passivation layer 230 has a thickness in the range of about 8 kÅ to about 20 kÅ, though other thicknesses are possible. In this manner, a capacitor 146 may be formed, though a capacitor 146 may have a different configuration or may be formed using other manufacturing steps in other embodiments.

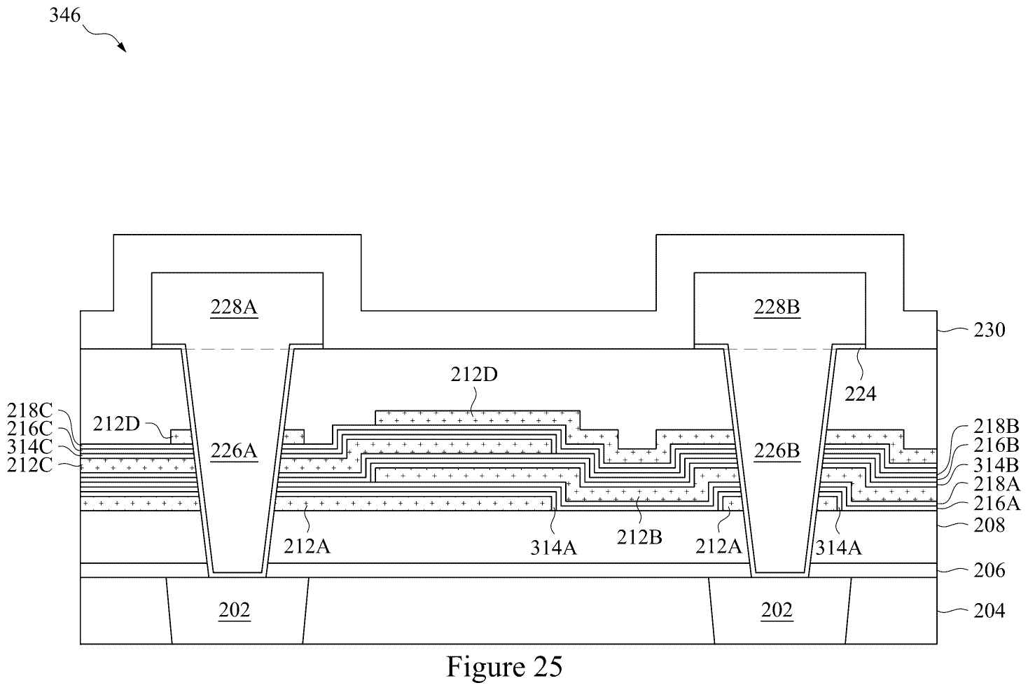

FIGS. 19 through 25 illustrate cross-sectional views of intermediate steps in the formation of a capacitor 346 (see FIG. 25), in accordance with some embodiments. The capacitor 346 is similar to the capacitor 146 described for FIGS. 1-18, except that the bottom barrier layers 314 of the capacitor 346 are formed using an oxidation process rather than a deposition process. For example, the capacitor 346 utilizes both bottom barrier layers 314 and top barrier layers 218 to achieve benefits such as those described previously for the capacitor 146. A capacitor 346 may be utilized in a similar manner as the embodiments described herein for the capacitor 146. For example, a capacitor 346 may be utilized as a capacitor 146A, 146B, or 146C shown in FIG. 1. The capacitor 346 may be formed using some materials or techniques that are similar to those described previously for the capacitor 146, and as such some details may not be repeated.

In FIG. 19, an oxidation process is performed on the electrodes 212A to form bottom barrier layers 314A, in accordance with some embodiments. The electrodes 212A shown in FIG. 19 may be similar to the electrodes 212A described previously for FIG. 5, and may be formed using similar techniques. For example, the electrodes 212A shown in FIG. 19 may be formed of titanium nitride, though other materials are possible. Accordingly, the structure shown in FIG. 19 may follow from the structure shown in FIG. 5. In other embodiments, a single electrode 212A or another number of electrodes 212A may be formed. In some embodiments, an electrode 212A may be separated or otherwise electrically isolated from another electrode 212A.

In some embodiments, the oxidation process oxidizes surface portions of the electrodes 212A, forming bottom barrier layers 314A comprising an oxide of the material of the electrodes 212A. As an example, for embodiments in which the electrodes 212A are titanium nitride, the oxidation process converts surface portions of the titanium nitride into a layer of titanium oxynitride (e.g., TiON). In this manner, the layer of titanium oxynitride forms bottom barrier layers 314A that cover the electrodes 212A. In some embodiments, the oxidation process may leave other surfaces exposed, such as surfaces of the dielectric layer 208. The number of bottom barrier layers 314A formed may depend on the number of electrodes 212A present, and another number of bottom barrier layers 314A is possible in other embodiments.

In some embodiments, the oxidation process may be performed using an oxygen-containing process gas such as oxygen (O₂), water steam or water vapor (H₂O), the like, or a combination thereof. Other process gases are possible. The oxidation process may be performed at a temperature in the range of about 250° C. to about 400° C. The oxidation process may be performed for a duration in the range of about 5 seconds to about 60 seconds. Other process parameters are possible. In accordance with some embodiments, the bottom barrier layers 314A formed by the oxidation process have a thickness in the range of about 5 Å to about 40 Å, though other thicknesses are possible.

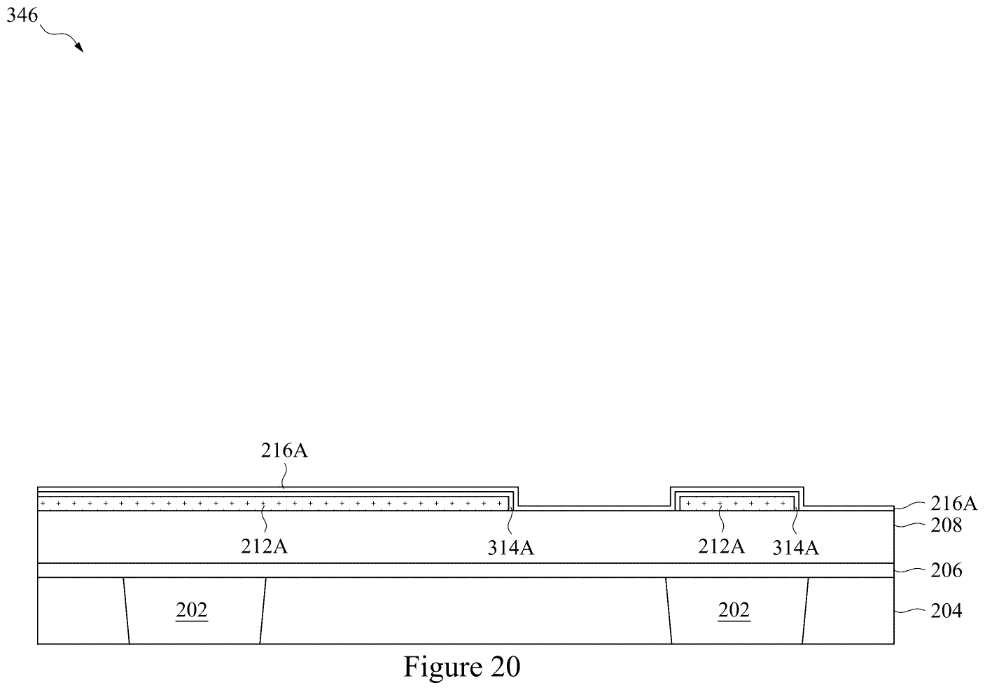

In FIG. 20, an insulator 216A is deposited over the bottom barrier layers 314A and the dielectric layer 208, in accordance with some embodiments. The insulator 216A may be similar to the insulator 216A described previously for FIG. 7, and may be formed using similar techniques. As shown in FIG. 20, in some embodiments, portions of the insulator 216A may be deposited on exposed surfaces of the dielectric layer 208.

In FIG. 21, a top barrier layer 218A is deposited over the insulator 216A, in accordance with some embodiments. The top barrier layer 218A may be similar to the top barrier layer 218A described previously for FIG. 8, and may be formed using similar techniques. For example, the top barrier layer 218A may be formed using ALD, PEALD, thermal ALD, or the like.

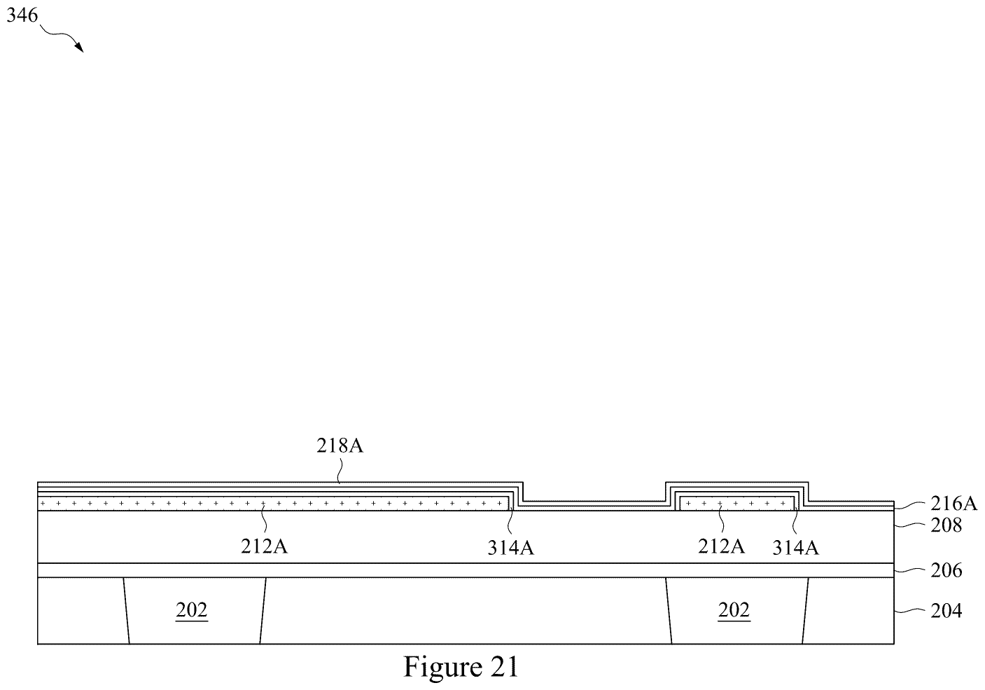

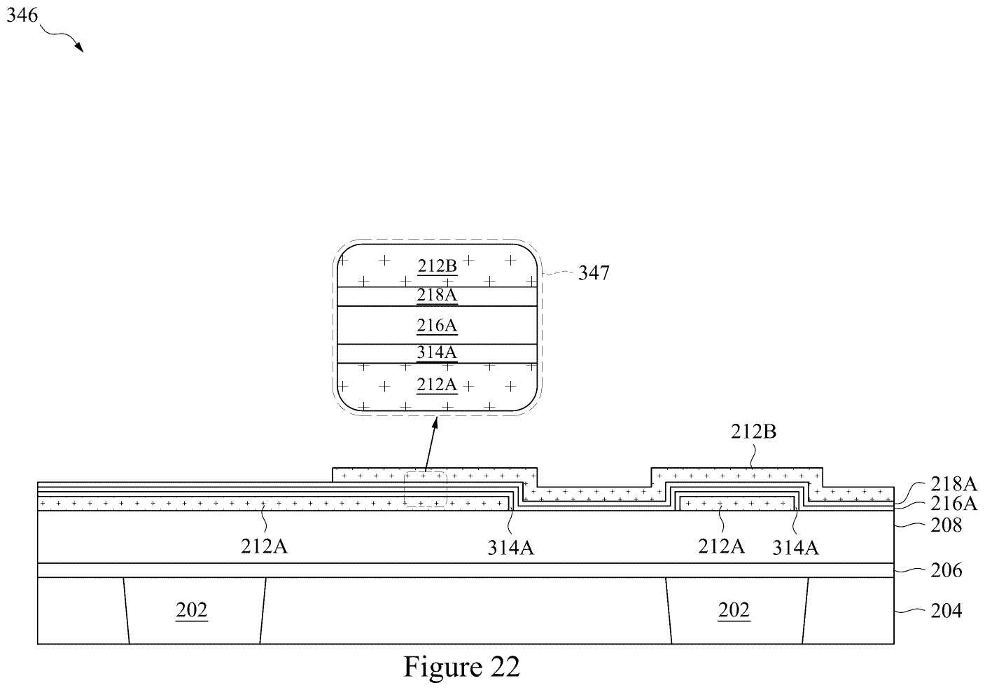

In FIG. 22, an electrode 212B is formed over the top barrier layer 218A, in accordance with some embodiments. FIG. 22 also illustrates a magnified view 347 of a portion of the structure. The electrode 212B may be similar to the electrode 212B described previously for FIG. 11, and may be formed using similar techniques. For example, an electrode layer (e.g., similar to electrode layer 210B) may be deposited over the structure and patterned using an etching mask (e.g., similar to etching mask 213).

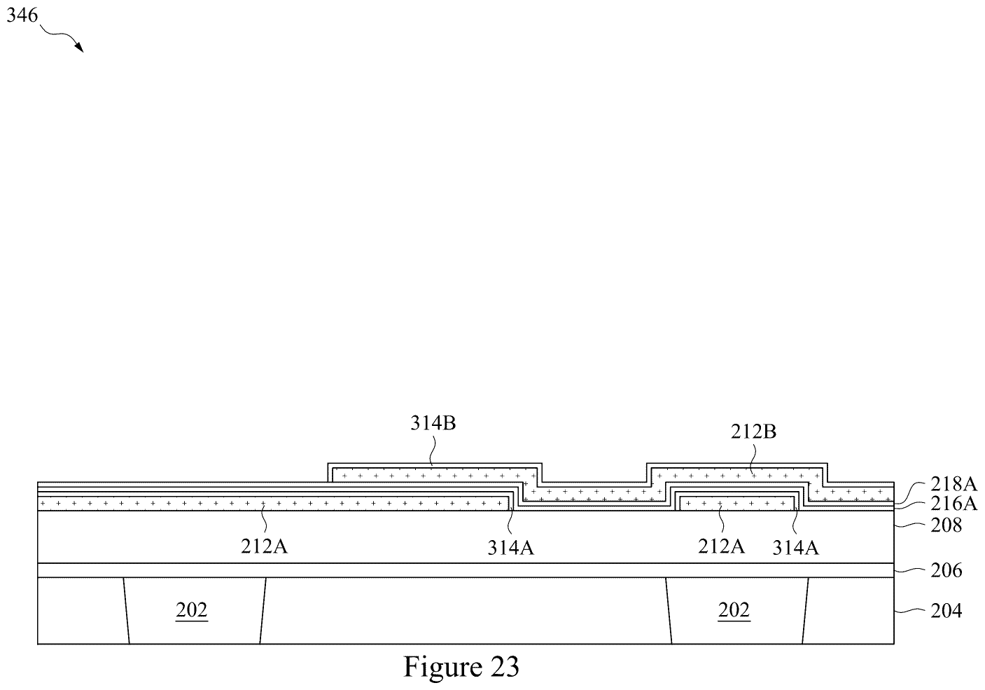

In FIG. 23, a bottom barrier layer 314B is formed using an oxidation process, in accordance with some embodiments. The bottom barrier layer 314B may be formed by performing an oxidation process to convert surface portions of the electrode 212B into an oxide material, similar to the formation of the bottom barrier layer 314A. The oxidation process may be similar to the oxidation process described previously for forming the bottom barrier layer 314A. Accordingly, the bottom barrier layer 314B may be similar to the bottom barrier layer 314A, in some embodiments. As shown in FIG. 23, portions of the top barrier layer 218A may remain exposed after performing the oxidation process, in some embodiments.

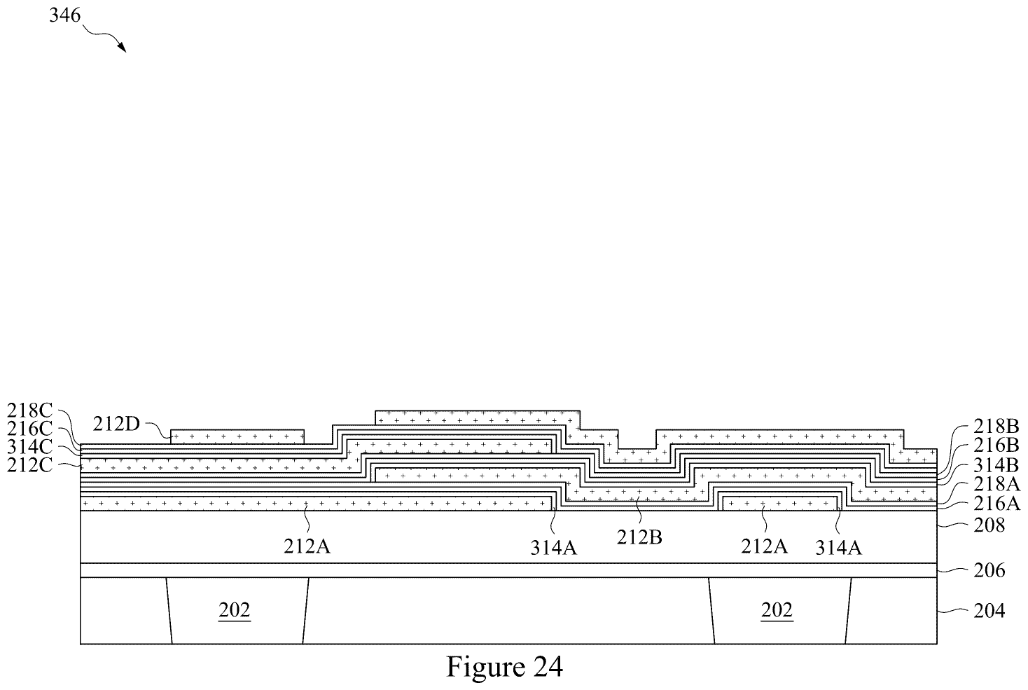

FIG. 24 illustrates the formation of an electrode 212C, a bottom barrier layer 314C, an insulator 216C, a top barrier layer 218C, and electrodes 212D, in accordance with some embodiments. The electrodes 212C-D may be formed using materials or techniques similar to those described previously for the electrodes 212A-B. The bottom barrier layer 314C may be formed by performing an oxidation process on the electrode 212C, similar to the formation of the bottom barrier layers 314A-B. The insulators 216B-C may be formed using materials or techniques similar to those described previously for the insulator 216A, and the top barrier layer 218C may be formed using materials or techniques similar to those described previously for the top barrier layers 218A-B. In some embodiments, the materials or techniques for forming the features may be different from those described previously for corresponding features. For example, in other embodiments, a capacitor may have both bottom barrier layer(s) 214 formed using deposition (e.g., ALD or the like) and bottom barrier layer(s) 314 formed using an oxidation process.

FIG. 25 illustrates the formation of contact plugs 226A-B and the conductive lines 228A-B, in accordance with some embodiments. The contact plugs 226A-B and conductive lines 228A-B may be similar to the corresponding features shown in FIG. 18, and may be formed using materials or techniques similar to those described previously for FIG. 14-18. For example, a dielectric layer 220 may be formed over the structure, openings (e.g., similar to openings 222) may be etched, and conductive material may be deposited (e.g., plated) to form the contact plugs 226A-B and conductive lines 228A-B. A passivation layer 230 may be formed, in some embodiments. In this manner, a capacitor 346 may be formed, though a capacitor 346 may have a different configuration or may be formed using other manufacturing steps in other embodiments.

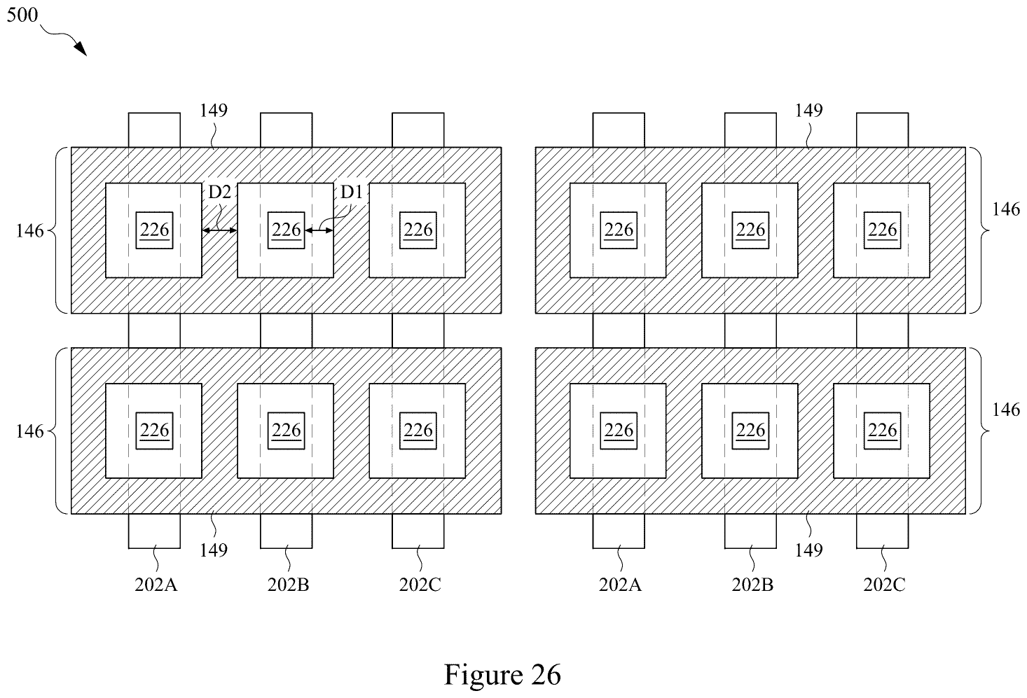

FIG. 26 shows a plan view of a portion of a device 500 comprising multiple capacitors 146, in accordance with some embodiments. The device 500 may be, for example, a semiconductor die, a chip, a package, an interposer, another structure or device, or the like. The plan view shown in FIG. 26 is an illustrative example, and other configurations, layouts, or arrangements are possible. FIG. 26 illustrates a plurality of contact plugs 226 electrically contacting underlying conductive features 202A-C. The conductive features 202A-C may be, for example, conductive lines or the like. Sets of contact plugs 226 are capacitively coupled by capacitors 146. For example, FIG. 26 illustrates capacitors 146 that couple three contact plugs 226 respectively connected to each conductive feature 202A-C. In other embodiments, a capacitor 146 may couple a set of two contact plugs 226 or a set of more than three contact plugs 226. The conductive features 202A-C may correspond to similar or different voltages. For example, in some embodiments, the conductive features 202A and 202C may be coupled to one power supply voltage, and the conductive features 202B may be coupled to a second power supply voltage. Other configurations are possible.

As an example, FIG. 26 illustrates the capacitive region 149 of each capacitor 146. The capacitive region 149 may fully or partially surround (e.g., encircle) one or more contact plugs 226, as shown in FIG. 26. In other embodiments, the capacitive region 149 may be present only between neighboring contact plugs 226. Other arrangements of the capacitive region 149 are possible. The capacitive region 149 may be offset from each contact plug 226, such as by a distance D1 in the range of about 0.2 μm to about 1.2 μm, though other distances are possible. In some embodiments, the capacitive region 149 between neighboring contact plugs 226 may have a width D2 that is in the range of about 0.2 μm to about 2 μm, though other widths are possible. In this manner, multiple capacitors 146 may be utilized, e.g., to reduce noise or voltage fluctuation in a device 500.

The embodiments of the present disclosure have some advantageous features. By forming a barrier layer on both sides of the insulator layers of a capacitor, the electric field across the insulator can be reduced for both forward bias and reverse bias. By reducing the electric field across the insulator for both bias polarities, the capacitor may have improved reliability and increased lifetime. Forming a “symmetric” capacitor structure in this manner can also achieve more uniform capacitance across both bias polarities. The techniques described herein can allow for improved capacitor performance without significantly decreasing the capacitance of a capacitor. The capacitor described herein is thus suitable for utilization as a decoupling capacitor, for example.

In accordance with some embodiments of the present disclosure, a method includes forming a first capacitor electrode; forming a first oxygen-blocking layer on the first capacitor electrode; forming an capacitor insulator layer on the first oxygen-blocking layer; forming a second oxygen-blocking layer on the capacitor insulator layer; forming a second capacitor electrode on the second oxygen-blocking layer; and forming a first contact plug that is electrically coupled to the first capacitor electrode and a second contact plug that is electrically coupled to the second capacitor electrode. In an embodiment, forming the first contact plug includes etching an opening that exposes sidewalls of the first capacitor electrode, the first oxygen-blocking layer, the capacitor insulator layer, and the second oxygen-blocking layer; and depositing a conductive material in the opening, wherein the conductive material physically contacts the exposed sidewalls of the first capacitor electrode, the first oxygen-blocking layer, the capacitor insulator layer, and the second oxygen-blocking layer. In an embodiment, forming the first oxygen-blocking layer includes performing an oxidation process on the first capacitor electrode. In an embodiment, forming the first oxygen-blocking layer includes performing an Atomic Layer Deposition (ALD) process. In an embodiment, the first oxygen-blocking layer is a different material than the second oxygen-blocking layer. In an embodiment, the first oxygen-blocking layer includes titanium oxynitride. In an embodiment, forming the capacitor insulator layer includes depositing a layer of hafnium zirconium oxide using an ALD process. In an embodiment, the second oxygen-blocking layer has a thickness in a range of 5 Å to 30 Å.

In accordance with some embodiments of the present disclosure, a method includes depositing a first conductive material over a dielectric layer; patterning the first conductive material to form a first electrode; depositing a first barrier layer over the first electrode as a blanket layer, wherein the first barrier layer includes a first metal oxide; depositing a first insulator layer over the first barrier layer as a blanket layer, wherein the first insulator layer includes a second metal oxide that is different from the first metal oxide; depositing a second barrier layer over the first insulator layer as a blanket layer, wherein the second barrier layer includes the first metal oxide; depositing a second conductive material on the second barrier layer; and patterning the second conductive material to form a second electrode. In an embodiment, the method includes forming a first contact plug penetrating the first electrode and a second contact plug penetrating the second electrode. In an embodiment, the first metal oxide includes titanium oxide. In an embodiment, the method includes depositing a third barrier layer over the second electrode; depositing a second insulator layer over the third barrier layer; depositing a fourth barrier layer over the second insulator layer; depositing a third conductive material on the fourth barrier layer; and patterning the third conductive material to form a third electrode. In an embodiment, the first insulator layer physically contacts a top surface of the dielectric layer. In an embodiment, the first conductive material and the second conductive material are titanium nitride. In an embodiment, a thickness of the first barrier layer is different from a thickness of the second barrier layer.

In accordance with some embodiments of the present disclosure, a device includes a first via on a first conductive feature; a second via on a second conductive feature; and a capacitive stack including electrode layers including first electrode layers and second electrode layers, wherein the first electrode layers are arranged alternatingly with the second electrode layers, wherein the first electrode layers are electrically coupled to the first via and the second electrode layers are electrically coupled to the second via; insulator layers, wherein each insulator layer is between a respective first electrode layer and a respective second electrode layer, first barrier layers, wherein each first barrier layer is between a bottom surface of a respective insulator layer and a top surface of a respective electrode layer; and second barrier layers, wherein each second barrier layer is between a top surface of a respective insulator layer and a bottom surface of a respective electrode layer. In an embodiment, each first barrier layer physically contacts the respective insulator layer and the respective electrode layer. In an embodiment, the first barrier layers are a different material than the second barrier layers. In an embodiment, at least one second barrier layer physically contacts two respective insulator layers. In an embodiment, the first via physically contacts the first electrode layers, the insulator layers, and the second barrier layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1-20. (canceled)

21. A device comprising:
a first contact plug over a substrate;
a second contact plug over the substrate;
first dielectric layer extending from a first sidewall of the first contact plug to a second sidewall of the second contact plug;
a first conductive layer extending on the first electric layer, wherein the first conductive layer contacts the first sidewall;
a first layer of a first metal oxide extending on the first conductive layer and on the first dielectric layer, wherein the first layer of the first metal oxide extends from the first sidewall to the second sidewall;
a first layer of a second metal oxide extending on the first layer of the first metal oxide, wherein the first layer of the second metal oxide extends from the first sidewall to the second sidewall;
a second layer of the first metal oxide extending on the first layer of the second metal oxide, wherein the second layer of the first metal oxide extends from the first sidewall to the second sidewall;
a second conductive layer extending on the second layer of the first metal oxide, wherein the second conductive layer contacts the second sidewall;
a third layer of the first metal oxide extending on the second conductive layer and on the second layer of the first metal oxide, wherein the third layer of the first metal oxide extends from the first sidewall to the second sidewall;
a second layer of the second metal oxide extending on the third layer of the first metal oxide, wherein the second layer of the second metal oxide extends from the first sidewall to the second sidewall;
a fourth layer of the first metal oxide extending on the second layer of the second metal oxide, wherein the fourth layer of the first metal oxide extends from the first sidewall to the second sidewall; and
a third conductive layer extending on the fourth layer of the first metal oxide, wherein the third conductive layer contacts the first sidewall.

22. The device of claim 21, wherein the first layer of the first metal oxide and the second layer of the first metal oxide have different thicknesses.

23. The device of claim 21, wherein the first metal oxide is a titanium oxide.

24. The device of claim 21, wherein the second metal oxide is free of titanium.

25. The device of claim 21, wherein the first sidewall faces the second sidewall.

26. The device of claim 21, wherein the first contact plug and the second contact plug extend through the first dielectric layer.

27. The device of claim 21, wherein the first layer of the second metal oxide has a thickness in the range of 30 Å to 100 Å.

28. The device of claim 21, wherein the first layer of the second metal oxide is free of the second layer of the second metal oxide.

29. A device comprising:
a first electrode layer over a substrate;
a first barrier layer covering a top surface and a sidewall of the first electrode layer;
a first insulator layer covering a top surface and a sidewall of the first barrier layer;
a second barrier layer covering a top surface and a sidewall of the first insulator layer; and
a second electrode layer covering a top surface and a sidewall of the second barrier layer, wherein the first insulator layer is free of the first electrode layer and the second electrode layer, wherein a bottom surface of the second electrode layer is closer to the substrate than a top surface of the first electrode layer.

30. The device of claim 29, wherein the second barrier layer has a thickness in the range of 5 Å to 30 Å.

31. The device of claim 29, wherein the first barrier layer and the second barrier layer are different materials.

32. The device of claim 29, wherein the second barrier layer is a layer of zirconium oxide.

33. The device of claim 29, wherein the first barrier layer is a layer of titanium oxynitride.

34. The device of claim 29, wherein bottom surfaces of the first insulator layer and the first electrode layer are level.

35. A method comprising:
conformally depositing a first electrode on a first dielectric layer;
conformally depositing a first oxygen-blocking layer over the first electrode using a first deposition process;
conformally depositing a first high-k layer over the first oxygen-blocking layer;
conformally depositing a second oxygen-blocking layer over the first high-k layer using an atomic layer deposition (ALD) process;
conformally depositing a second electrode on the second oxygen-blocking layer;
forming a first contact plug that penetrates the first electrode, the first oxygen-blocking layer, the first high-k layer, and the second oxygen-blocking layer; and
forming a second contact plug that penetrates the first oxygen-blocking layer, the first high-k layer, the second oxygen-blocking layer, and the second electrode.

36. The method of claim 35, wherein the first deposition process comprises a thermal oxidation process.

37. The method of claim 35, wherein the first deposition process comprises an ALD process.

38. The method of claim 35, wherein the second electrode is deposited after the second oxygen-blocking layer is deposited.

39. The method of claim 35, wherein the first oxygen-blocking layer has a larger concentration of nitrogen than the second oxygen-blocking layer.

40. The method of claim 35 further comprising conformally depositing a third oxygen-blocking layer on the second electrode and on the second oxygen-blocking layer using a second deposition process.
